(19) United States
(12) Patent Application Publication
(10) Pub. No.: US 2003/0078354 A1
(43) Pub. Date: Apr. 24, 2003

(54) Novel beta-oxo compounds and their use in photoresist

(75) Inventors: Art Medina, Duluth, GA (US); Ilya Rushkin, Walpole, MA (US); Gregory Spaziano, Providence, RI (US); David Brzozowy, Bristol, RI (US)

Correspondence Address: Paul D. Greeley, Esq., Ohlandt, Greeley, Ruggiero & Perle, L.L.P., 10th Floor, One Landmark Square, Stamford, CT, 06901-2682, US

(73) Assignee: ARCH SPECIALTY CHEMICALS, INC., NORWALK, CT (US)

(21) Appl. No.: 10/081,732

(22) Filed: Feb. 21, 2002

Related U.S. Application Data
(60) Provisional application No. 60/270,773, filed on Feb. 23, 2001.

(51) Int. Cl. G03F 7/038; G03F 7/38; C08F 224/00; C08F 234/02; G03C 1/492; G03C 1/76

(52) U.S. Cl. 526/266; 430/270.1; 430/325; 430/905; 526/268; 526/270

(57) ABSTRACT

Polymers comprising monomeric units of acid sensitive (acid labile) monomers and from about 2 to about 20% by weight of monomeric units of β-oxo ester containing monomers, wherein the β-oxo ester containing monomers are free of lactams or lactones, are useful as binder resins in radiation sensitive photoresist compositions for producing a resist image on a substrate.

This application claims priority from Provisional Application Serial No. 60/270,773, filed on Feb. 23, 2001.

### BACKGROUND TO THE INVENTION

1. Field of the Invention

The present invention relates to a polymer derived from a β-oxo ester-containing monomer and a monomer having an acid labile group. More particularly, the present invention relates to a radiation sensitive photoresist composition including the above polymer and a method of producing a resist image on a substrate. The radiation sensitive photoresist compositions are used in photolithography for the production of semiconductor materials and devices.

2. Description of the Prior Art

The continuing drive for miniaturization of semiconductor devices has driven an increasing rigor in the photolithography used to delineate the fine patterns of those devices. Imaging wavelengths have shrunk from 365 nm (high pressure mercury lamp) to 248 nm (KrF excimer lasers), to 193 nm (ArF excimer lasers) and beyond. As the patterns and wavelengths become finer, the materials properties of the photoresists used for pattern delineation have become more and more demanding. In particular, requirements of sensitivity, transparency, quality of the image produced, and the selectivity of the resists to etch conditions for pattern transfer become more and more strenuous. Because of this, the traditional lithographic materials, such as diazonaphthoquinones, novolaks, etc., are unsuitable platforms for ULSI manufacture and beyond.

The principle of chemical amplification as a basis for photoresist operation has been known for some years (U.S. Pat. No. 4,491,628). The most ubiquitous chemically amplified resists are those based on derivatized styrene polymers. Many variations of this theme have been proposed and commercialized; J. Photopolym. Sci. and Technol., 11(3), 1998, pp. 379-394 provides an excellent summary of research efforts in Deep UV resist materials.

In 193-nm ArF excimer lithography, however, different materials are needed due to the high absorbance of the core styrene moieties. Acrylate platforms were proposed as vehicles for surmounting the transparency problem, but these systems were deficient in etch resistance (see J. Vac. Sci. Technol., B9, 3357 (1991), or J. Photopolym. Sci. and Technol., 8, No. 4,(1995) p. 623 or U.S. Pat. No. 5,580,694 for examples). These materials' etch resistance could be augmented by incorporation of pendant alicyclic moieties (see J. Photopolym. Sci. and Technol., 9, No. 3,(1996) p. 387; or J. Photopolym. Sci. and Technol.,9, No. 3,(1996) p. 475; or JP-A-973173 for possible alicyclics used), but the high hydrophobicity this imparted on the resins caused other processing problems, including de-wetting during development or adhesion loss or micropeeling.

Other classes of polymers based on cycloolefin monomers have been proposed in various forms (as disclosed in EP 789278 or JP-05-297591 for example). These polymers may be addition polymers, as disclosed in WO97/33198, or may be elaborated further by incorporation of maleic anhydride and acrylates as described in U.S. Pat. No. 5,843,624. However, these approaches again suffer from the high hydrophobicity imparted by the cyclooelfin leading to de-wetting during development or adhesion loss or micropeeling. U.S. Pat. No. 5,843,624 suggests that this problem may be overcome by incorporation of a free acid moiety. The acid also imparts a high dissolution rate to the photoresist, however, even in unexposed areas. This leads to loss of contrast as well as poor pattern quality due to top-rounding and film loss. U.S. Pat. No. 6,124,074 discloses cycloolefin-based photoresists, which have a non-acidic polar group pendant from the cycloolefin, without specifying the nature of the group.

A number of examples in the art employ hydroxyl-containing materials to increase the hydrophilicity. U.S. Pat. No. 6,100,011 discloses the use of hydroxyalkyl acrylates, as does U.S. Pat. No. 6,004,720 (Example 10). The use of hydroxyalkyl esters of cycloolefin carboxylic acids in positive-imaging systems is disclosed in GB 2332902A, GB 2332679A, GB 2320718A, GB 2320717A, GB 2340830A, GB 2340831A, EP 0930541A1 (see Example 6), and in U.S. Pat. No. 6,028,153 and U.S. Pat. No. 6,132,296. The technology can also be used for the generation of negative images, as is disclosed in patent applications GB 2344104 and GB 2344105. Hydroxyalkyl groups are also used as pendant groups of other monomers, for example in maleimide monomers (U.S. Pat. No. 6,028,153, GB 2336845A, and GB 2336846A). One drawback of this approach is that it is highly platform specific: in the case of the cycloolefin/maleic anhydride polymers, the hydroxyl groups are known to react with the maleic anhydride units (J. Photopolym. Sci. and Technol., 10, No. 4,(1997) p. 535), a reaction which also produces carboxylic acid in the polymer, whose effects have already been discussed.

A third approach has been to incorporate a cyclic derivatized carboxylic acid as a pendant group in the polymer. The use of lactones (cyclic carboxylic esters) is disclosed in U.S. Pat. No. 5,968,713, U.S. Pat. No. 6,013,416, EP 1020767A1 and references contained therein, EP 0930541A1 (see Example 12), EP 0999474A1, in J. Photopolym. Sci. and Technol., 10, No. 4,(1997) p. 545, in J. Photopolym. Sci. and Technol., 9, No. 3,(1996) p. 509 and Ibid., p. 475. Use of lactams (cyclic carboxylic amides) is disclosed, for example, in U.S. Pat. No. 5,750,680, and in U.S. Pat. No. 6,051,362. These materials are very expensive to manufacture, however. Additionally, the lactones and lactams may ring-open during the post-exposure bake step, leading to undesired side reactions.

A fourth approach has been to employ ether groups as a hydrophillicity enhancer. Use of the ether as a side-group on cyclic lactams is disclosed in U.S. Pat. No. 6,087,065 or U.S. Pat. No. 5,888,698. U.S. Pat. No. 6,027,854 and U.S. Pat. No. 6,033,828 disclose the use of linear ethers or glycols as pendant groups for hydroxystyrene-based polymers. EP 1031879A1 and EP 1004568 disclose the use of these groups in cycloolefin-based systems. J. Photopolym. Sci. and Technol., 10, No. 4,(1997) p. 545 however, shows that the performance of the ethers is inferior to the lactones, for example. In this paper, a polymer containing tetrahydrofurfuryl methacrylate was shown to have poor imaging and adhesion compared with a polymer containing the same molar ratio of mevalonic lactone acrylate.

Cyclic carbonate molecules have also been used for improving the hydrophillicity of the binder resins. In U.S. Pat. No. 6,048,661, 1-acryloyl-2,3-glycerol carbonate is used as a polarity enhancing group (see Polymer 38). However, in EP 1004568A2, Polymers 24-28, the performance of polymers containing this monomer is shown to be substantially inferior to the other examples given. GB 2320718 and U.S. Pat. No. 6,132,296 disclose a carbonate monomer (vinylene carbonate) which is part of the backbone of the polymer; this monomer is expensive, however, and may undergo a hydrolysis reaction, which would lower the Tg of the polymer.

Finally, in U.S. Pat. No. 5,929,271 and U.S. Pat. No. 6,077,644 a specific monomer or polymer containing that monomer, and in U.S. Pat. No. 6,087,063 a more generic class of monomer are disclosed which contain ketone groups.

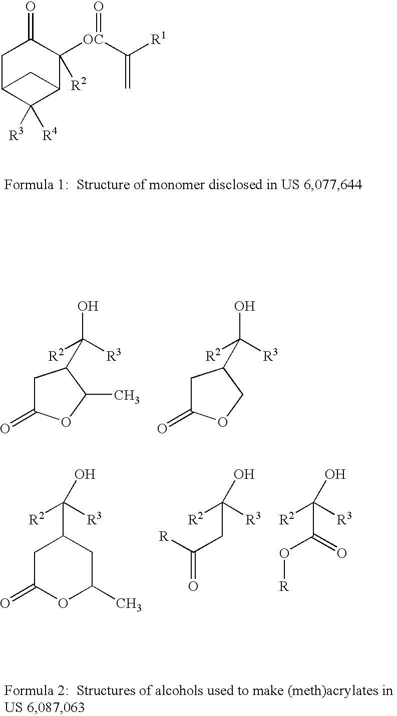

These patents teach that use of acid-cleavable lactone, alkoxycarbonyl, or ketone groups in relatively high amounts in a polymeric binder resin for photolithography results in a material, which has a better adhesion to the substrate. The group must be acid-cleavable, and must be present in amounts greater than 20%. In this fashion, however, the group imparts some undesirable properties to the resulting polymer, including greater tendency to emit gaseous material during exposure and processing bakes, and a greater tendency of the material to shrink during metrology with a scanning electron microscope.

### SUMMARY OF THE INVENTION

The present invention provides a polymer prepared by polymerizing a mixture of monomers, including: at least one monomer having an acid labile group; and at least one β-oxo ester containing monomer, which is free of a lactone group. The polymers include monomeric units of acid sensitive (acid labile) monomers and from about 2 to about 20% by weight of monomeric units of β-oxo ester containing monomers, wherein the β-oxo ester containing monomers are free of lactones.

The present invention further provides radiation sensitive photoresist compositions of (a) the above polymers as binder resins, (b) a photoacid generator compound, and (c) a solvent capable of dissolving components (a) and (b).

The present invention still further provides a method of producing a resist image on a substrate. The method employs photoresist compositions including the polymers of the present invention for lithographic production of imagewise patterns on semiconductor substrates. The method includes the steps of coating the substrate with a radiation senstive photoresist composition according to the present invention, imagewise exposing the photoresist composition to actinic radiation, and developing the photoresist composition with a developer to produce a resist image.

The polymers of this invention are polymers that include at least the two following polymerized monomeric units: [acid sensitive-containing monomeric unit]ₓ [β-oxo ester-containing monomeric unit]_{y} wherein the β-oxo ester-containing monomeric unit is not a lactam or lactone.

It will be appreciated that the polymers can and often will contain other monomeric units, as discussed herein after, in addition to the above mentioned two monomeric units.

### DETAILED DESCRIPTION OF THE INVENTION

The present invention relates to polymers that include polymerized units of the following monomeric units, namely an acid sensitive monomeric unit and a β-oxo ester-containing monomeric unit as described herein before. The polymers of this invention can include polymerized monomeric units of any β-oxo ester-containing monomeric unit so long as that unit is not a lactam or lactone.

Preferably, the β-oxo ester containing monomer has an ethylenically unsaturated ester portion and a β-oxo group containing portion covalently bonded to the oxygen of the ester group of the ethylenically unsaturated ester portion through a covalent bond between the oxygen of the ethylenically unsaturated ester portion and the CHR₁-group of the β-oxo group containing portion. The covalent bond can be represented as follows:

—O—CHR₁—

wherein R₁ is alkyl, haloalkyl or an alkylene residue.

However, in a preferred form, the present invention relates to the polymers including small amounts of from about 2 to about 20% by weight of polymerized units of β-oxo esters of carboxylic acid-containing compounds as monomers, and to the use of such polymers as photoresist binder resins wherein these β-oxo ester-containing monomeric unit can take any of the forms shown below in Formula 3 or 4:

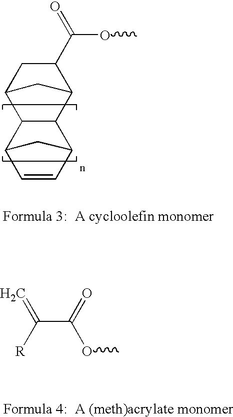

wherein R is selected from the group consisting of: hydrogen, C₁₋₄ alkyl group, CH₂CN, CH₂OR⁴, CH₂C(═O)OR⁴, CH₂OC(═O)R⁴, wherein R⁴ is selected from the group consisting of: substituted or unsubstituted C₁-C₁₀ linear, branched, or cyclic alkyl; substituted or unsubstituted C₁-C₁₀ linear, branched, cyclic or alicyclic alkylene group; and n is an integer of from 0 to 2; and

wherein the covalently bonded β-oxo group containing portion is represented by the formulas 5, 6a, 6b, 7, 8, 9 or 10:

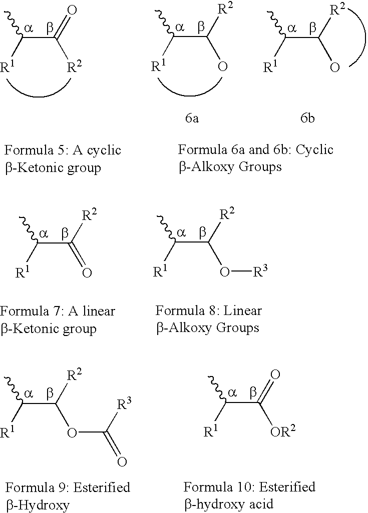

wherein in formula 5, R₁ and R₂ together represent an alkylene group of 2 to 5 carbon atoms to form a 4-, 5-, 6- or 7-membered ring having a β-oxo group;

wherein in formula 6a, R₂ can be hydrogen and a C₁₋₄ alkyl group and R₁ represents an alkylene group of 1 to 4 carbon atoms to form a 4-,5-, 6- or 7-membered ring having a β-oxo group;

wherein in formula 6b, R₁ can be hydrogen and a C₁₋₄ alkyl group and R₂ represents an alkylene group of 2 to 5 carbon atoms to form a 4-,5-, 6- or 7-membered ring having a β-oxo group;

wherein in formula 7, each of R₁ and R₂ can independently be hydrogen, substituted or unsubstituted linear, branched, cyclic C₁₋₁₀ alkyl group; C₁-C₁₀ fluoroalkyl or substituted or unsubstituted linear, branched, cyclic or alicyclic C₇₋₁₅ alkylene group;

wherein in formula 8, each of R₁, R₂ and R₃ can independently be hydrogen, substituted or unsubstituted linear, branched, cyclic C₁₋₁₀ alkyl group; C₁-C₁₀ fluoroalkyl or substituted or unsubstituted linear, branched, cyclic or alicyclic C₇₋₁₅ alkylene group;

wherein in formula 9, each of R₁, R₂ and R₃ can independently be hydrogen, substituted or unsubstituted linear, branched, cyclic C₁₋₁₀ alkyl group; C₁-C₁₀ fluoroalkyl or substituted or unsubstituted linear, branched, cyclic or alicyclic C₇₋₁₅ alkylene group; and

wherein in formula 10, each of R₁ and R₂ can independently be hydrogen, substituted or unsubstituted linear, branched, cyclic C₁₋₁₀ alkyl group; C₁-C₁₀ fluoroalkyl or substituted or unsubstituted linear, branched, cyclic or alicyclic C₇₋₁₅ alkylene group.

The preferred R group in the ethylenically unsaturated ester portion in formula 4 can be hydrogen, methyl, ethyl, n-butyl, i-butyl, n-propyl, i-propyl, CH₂CN, CH₂OMe, CH₂O-adamantyl, CH₂OCH₂-adamantyl, CH₂O-cyclohexyl, CH₂O-norbornyl, CH₂OCF₃, CH₂C(═O)OMe, CH₂C(═O)O-cyclopenyl, CH₂C(═O)O-i-propyl, CH₂C(═O)CF₃, CH₂C(═O)OCH₂-cyclohexyl, CH₂OC(═O)CH₂Br, CH₂OC(═O)CH₂Cl, CH₂OC(═O)CF₃, CH₂OC(═O)Me, CH₂OC(═O)-norbornyl, CH₂OC(═O)-adamantyl, CH₂OC(═O)-cyclohexyl or CH₂OC(═O)-tert-butyl.

Examples of such covalently bonded β-oxo group in formula 6a include the following groups:

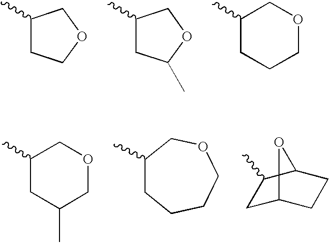

and examples of such covalently bonded β-oxo group in formula 6b include the following groups:

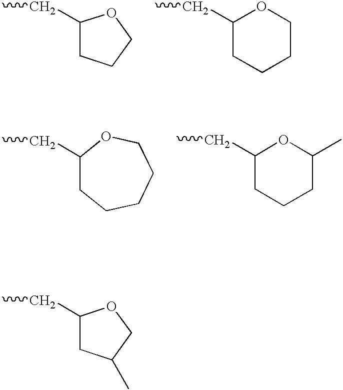

R¹ and R² groups in formula 7 can independently be hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl or norbornyl. Examples of such covalently bonded β-oxo group include the following:

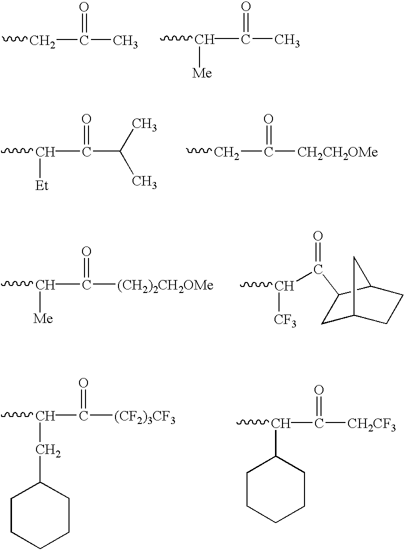

R¹ and R² groups in formula 8 can be hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl and norbornyl; and R³ is selected from the group consisting of: methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl, adamantyl or norbornyl. Examples of such groups are represented by the following formulas:

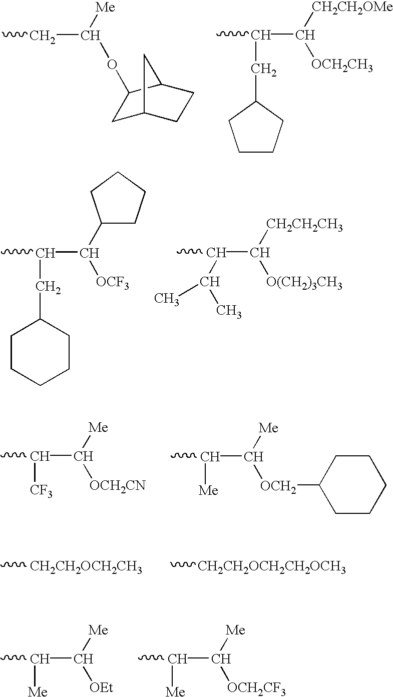

R¹ and R² groups in formula 9 can be hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl and norbornyl; and R³ is selected from the group consisting of: methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl, adamantyl or norbornyl. Such groups are exemplified by the following formulas:

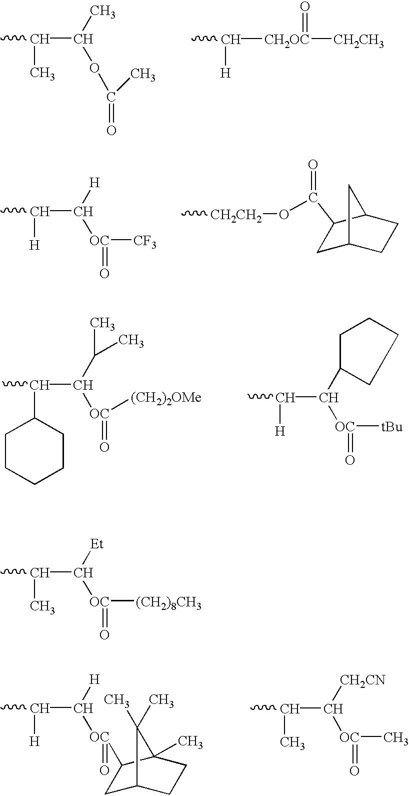

R¹ and R² groups in formula 10 can be, for example, hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl and norbornyl; and R³ is selected from the group consisting of: methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl, adamantyl or norbornyl. Examples of such covalently bonded β-oxo groups in formula 10include the following:

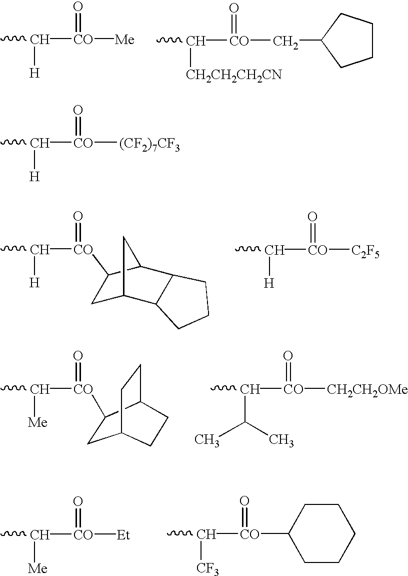

As described above, the β-oxo ester containing monomer has an ethylenically unsaturated ester portion and a β-oxo group containing portion covalently bonded to the oxygen of the ester group of the ethylenically unsaturated ester portion through the group represented by the formula:

—O—CHR₁—

wherein R₁ is alkyl, haloalkyl or an alkylene residue. Examples of the β-oxo ester containing monomers according to the present invention include the following:

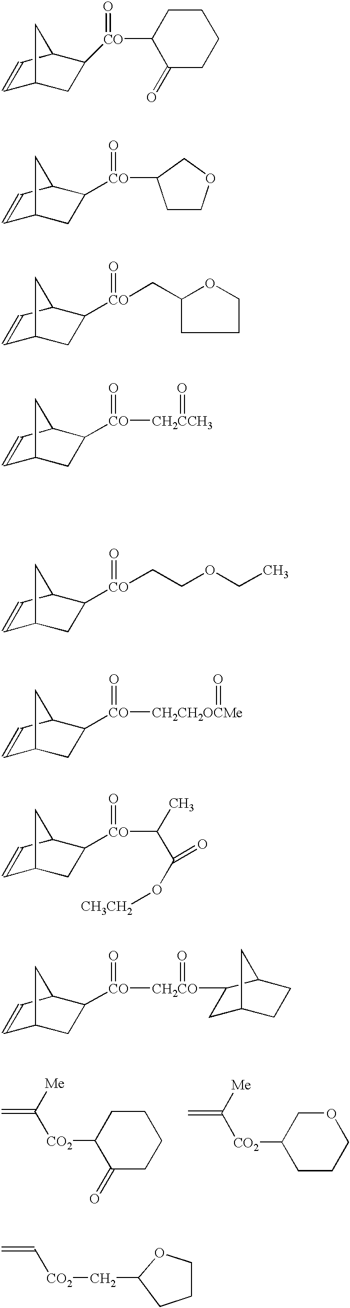

More preferably, the β-oxo ester-containing monomer is 3-acryloyl-2-butanone, ethyl lactate acrylate, tetrahydrofurfuryl norbornene carboxylate, tetrahydrofurfuryl acrylate, ethyl ethoxy norbornene carboxylate or ethyl lactyl norbornene carboxylate.

The acid sensitive group containing monomeric unit is produced from a monomer by polymerization. The monomer and subsequent monomeric unit contain an alkali-solubilizing group blocked by an acid sensitive group. Examples of such alkali solubilizing groups include but are not limited to carboxylic acids, hydroxyimides, hydroxyamides, sulfonamides, and fluorinated alcohols and the like. Examples of monomers with (unblocked) alkali solubilizing groups include but are not limited to the following examples:

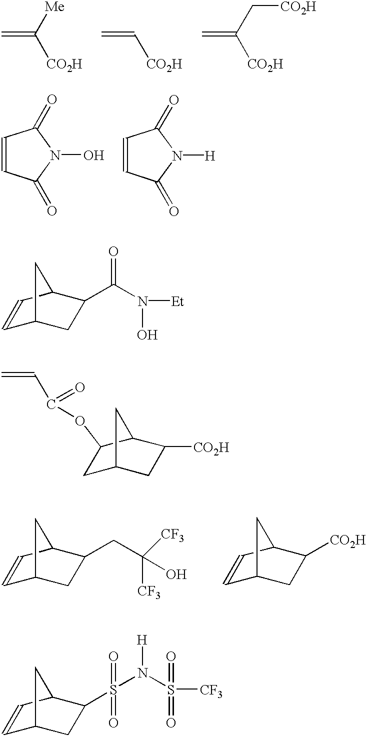

Acid sensitive groups, which are employed to block the alkali solubilizing groups, include but are not limited to tertiary ester groups, α-alkoxy esters, t-butoxycarbonate (tBOC) groups and acetal groups.

Examples of suitable monomers containing acid sensitive groups include, but are not limit to the following:

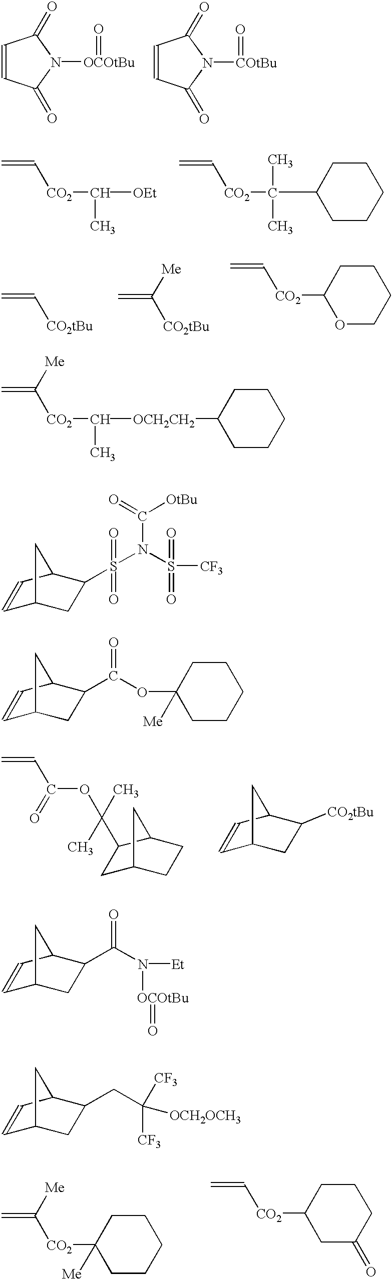

Examples of other suitable alkali solubilizing groups, monomers and monomeric units containing blocked alkali solubilizing units can be found in U.S. Pat. Nos. 6,329,125; 6,120,977; 6,013,416; and 5,985,522 herein incorporated by reference. Examples of other suitable monomers and monomeric units containing blocked alkali solubilizing units can be found in WO 00/25178, WO 00/67072 and WO 01/85811.

These monomers containing alkali solubilizing-groups blocked by acid sensitive groups can be used alone or in combination with other monomers containing alkali solubilizing groups blocked by acid sensitive groups.

As mentioned above, the mixture of monomers from which the polymers of the present invention are prepared can further include at least one comomomer, such as, styrene, naphthalene acrylate, naphthalene methacrylate, vinyl acetate, vinyl chloride, allyltrimethylsilane, vinyltrimethyl silane, norbornene, cyclohexene, maleic anhydride, dialkyl fumarate, maleimide, N-alkylmaleimide, N-arylmaleimide, sulfur dioxide, carbon monoxide, acrylamide, acrylate ester, methacrylate ester and mixtures thereof.

Preferably, such comonomers include norbornene, maleic anhydride, allyltrimethylsilane and naphthalene methacrylate.

Preferred polymers include copolymers, terpolymers, tetrapolymers and higher polymers, such as, for example, the following polymers: poly(norbornene-maleic anhydride-t-butylacrylate-3-acrolyl-2-butanone), poly(norbornene-maleic anhydride-t-butylacrylate-tetrahydrofurfuryl acrylate), poly(norbornene-maleic anhydridet-butylacrylate-ethyl lactate acrylate), poly(norbornene-maleic anhydride-t-butylacrylate-diethylene glycol acrylate), poly(allyltrimethylsilane-maleic anhydride-t-butylacrylate-3-acryloyl-2-butanone), poly(allyltrimethylsilane-maleic anhydride-t-butylacrylate-1-naphthalene methylacrylate-3-acryloyl-2-butanone), poly(allyltrimethylsilane-maleic anhydride-t-butylacrylate-1-naphthalene methylacrylate-tetrahydrofurfuryl acrylate), poly(tetrahydrofurfuryl norbornene carboxylate-maleic anhydride-methylcyclohexyl norbornene carboxylate), poly(ethoxyethyl norbornene carboxylate-maleic anhydride-methylcyclohexyl norbornene carboxylate, poly(ethyl lactate norbornene carboxylate-maleic anhydride-methylcyclohexyl norbornene carboxylate) and mixtures thereof.

The placement of the oxygen group must be on the β-carbon, i.e., the second carbon from the ester oxygen. This allows the use of small amounts of the monomer (e.g., of from about 2% to about 20%) to effect a good hydrophilicity. The nature of the oxygen is unimportant; as can be seen from the above structures, it can be carbonyl, carboxyl, or ether. It may not be hydroxyl, as this would react with other potential monomers in an undesirable way, nor can the oxygen be part of a cyclized carboxylate, e.g. lactone, or be part of a lactam as these would give rise to side reactions and thereby diminish the effectiveness of the group. Accordingly, the term “β-oxo ester” in the context of the present invention refers to an ester having an oxygen attached to the β-carbon, i.e., on the second carbon atom from the ester oxygen, but excluding the following oxygen containing groups: hydroxyl, lactone and lactam groups.

The present invention relates to polymers useful for fine pattern formation in lithographic processes, which include monomers of the type described above. As described above, many other comonomers could be employed, including but not limited to styrene, naphthalene and its derivatives, allyltrimethylsilane, cycloolefins, such as, norbornene or cyclohexene, maleic anhydride, dialkyl fumarates, sulfur dioxide, carbon monoxide, and other monomers which can polymerize with olefinic centers, and vinyl monomers such as acrylates, methacrylates, or other compounds with a polymerizable C═C bond.

The polymers of this invention can be made by conventional polymerizations known to those skilled in the art. Examples of suitable polymerization initiators include dialkyl peroxides, hydroperoxides, azo compounds and as required, chain-transfer agents.

The present invention further relates to photoresist compositions including those polymers. Many other additives, including photoacid generators, photobase generators, basic compounds for limiting diffusion lengths of photogenerated acids, crosslinkers, dissolution inhibitors, and the like may be included in useful photoresists according to the present invention.

Any suitable photoacid generator compounds can be used in the photoresist composition. The photoacid generator compounds are well known and include, for example, onium salts such as diazonium, sulfonium, sulfoxonium and iodonium salts, and disulfones. Suitable photoacid generator compounds are disclosed, for example, in U.S. Pat. Nos. 5,558,978 and 5,468,589, which are incorporated herein by reference.

Suitable examples of photoacid generators are phenacyl p-methylbenzenesulfonate, benzoin p-toluenesulfonate, α-(p-toluene-sulfonyloxy)methylbenzoin 3-(p-toluenesulfonyloxy)-2-hydroxy-2-phenyl-1-phenylpropyl ether, N-(p-dodecylbenzenesulfonyloxy)-1,8-naphthalimide and N-(phenyl-sulfonyloxy)-1,8-napthalimide.

Other suitable compounds are o-nitrobenzaldehydes which rearrange on actinic irradiation to give o-nitrosobenzoic acids such as 1-nitrobenzaldehyde and 2,6-nitrobenzaldehyde, α-haloacylphenones such as α,α,α-trichloroacetophenone and p-tert-butyl-α,α,α-trichloroacetophenone, and sulfonic esters of o-hydroxyacylphenones, such as 2-hydroxybenzophenone methanesulfonate and 2,4-hydroxybenzophenone bis(methanesulfonate).

Still other suitable examples of photoacid generators are triphenylsulfonium bromide, triphenylsulfonium chloride, triphenylsulfonium iodide, triphenylsulfonium hexafluorophosphate, triphenylsulfonium hexafluoroarsenate, triphenylsulfonium hexafluoroarsenate, triphenylsulfonium trifluoromethanesulfonate, diphenylethylsulfonium chloride, phenacyidimethylsulfonium chloride, phenacyltetrahydrothiophenium chloride, 4-nitrophenacyltetrahydro-thiopheniumn chloride and 4-hydroxy-2-methylphenylhexahydro-thiopyrylium chloride.

Further examples of suitable photoacid generators for use in this invention are bis(p-toluenesulfonyl)diazomethane, methylsulfonyl p-toluenesulfonyldiazomethane, 1-cyclo-hexylsulfonyl-1-(1,1-dimethylethylsulfonyl)diazometane, bis( 1,1-dimethylethylsulfonyl)-diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfony1)-propiophenone, 2-methanesulfonyl-2-methyl-(4-methylthiopropiophenone, 2,4-methy1-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, 2,4-dinitrobenzyl p-trifluoromethylbenzenesulfonate.

Other suitable examples of photogenerators include hexafluorotetrabromo-bisphenol A, 1,1,1-tris(3,5-dibromo-4-hydroxyphenyl)ethane and N-(2,4,6-tribromophenyl)-N′-(p-toluenesulfonyl)urea.

The photoacid generator compound is typically employed in the amounts of about 0.0001 to 20% by weight of polymer solids and more preferably about 1% to 10% by weight of polymer solids.

The choice of solvent for the photoresist composition and the concentration thereof depends principally on the type of functionalities incorporated in the acid labile polymer, the photoacid generator, and the coating method. The solvent should be inert, should dissolve all the components in the photoresist, should not undergo any chemical reaction with the components and should be re-removable on drying after coating. Suitable solvents for the photoresist composition may include ketones, ethers and esters, such as methyl ethyl ketone, methyl isobutyl ketone, 2-heptanone, cyclopentanone, cyclehexanone, 2-methoxy-1-propylene acetate, 2-methoxyethanol, 2-ethoxyethanol, 2-ethoxyethyl acetate, I-methoxy-2-propyl acetate, 1,2-dimethoxy ethane ethyl acetate, cellosolve acetate, propylene glycol monoethyl ether acetate, methyl lactate, ethyl lactate, methyl pyruvate, ethyl pyruvate, methyl 3-methoxypropionate, ethyl 3-methoxypropionate, N-methyl-2-pyrrolidone, 1,4-dioxane, ethylene glycol monoisopropyl ether, diethylene glycol monoethyl ether, diethylene glycol monomethyl ether, diethylene glycol dimethyl ether, and the like.

In an additional embodiment, base additives may be added to the photoresist composition. The purpose of the base additive is to scavenge protons present in the photoresist prior to being irradiated by the actinic radiation. The base prevents attack and cleavage of the acid labile groups by the undesirable acids, thereby increasing the performance and stability of the resist. The percentage of base in the composition should be significantly lower than the photoacid generator because it would not be desirable for the base to interfere with the cleavage of the acid labile groups after the photoresist composition is irradiated. The preferred range of the base compounds, when present, is about 3% to 50% by weight of the photoacid generator compound. Suitable examples of base additives are 2-methylimidazole, triisopropylamine, 4-dimethylaminopryidine, 4,4′-diaminodiphenyl ether, 2,4,5 triphenyl imidazole and 1,5-diazobicyclo[4.3.0]non-5-ene.

Dyes may be added to the photoresist to increase the absorption of the composition to the actinic radiation wavelength. The dye must not poison the composition and must be capable of withstanding the process conditions including any thermal treatments. Examples of suitable dyes are fluorenone derivatives, anthracene derivatives or pyrene derivatives. Other specific dyes that are suitable for photoresist compositions are described in U.S. Pat. No. 5,593,812.

The photoresist composition may further include conventional additives such as adhesion promoters and surfactants. A person skilled in the art will be able to choose the appropriate desired additive and its concentration.

The invention further relates to a process for forming a pattern on a substrate which includes the following process steps: application of a photoresist coating including one of the compositions described above to the substrate; imagewise exposure of the coating to actinic radiation; treatment of the coating with an alkaline aqueous developer until the areas of the coating which have been exposed to the radiation detach from the substrate and an imaged photoresist structured coating remains on the substrate.

The photoresist composition is applied uniformly to a substrate by known coating methods. For example, the coatings may be applied by spin-coating, dipping, knife coating, lamination, brushing, spraying, and reverse-roll coating. The coating thickness range generally covers values of about 0.1 to more than 10 μm. After the coating operation, the solvent is generally removed by drying. The drying step is typically a heating step called soft bake where the resist and substrate are heated to a temperature of about 5° C. to 150° C. for about a few seconds to a few minutes; preferably for about 5 seconds to 30 minutes depending on the thickness, the heating element and end use of the resist.

The photoresist compositions are suitable for a number of different uses in the electronics industry. For example, it can be used as electroplating resist, plasma etch resist, solder resist, resist for the production of printing plates, resist for chemical milling or resist in the production of integrated circuits. The possible coatings and processing conditions of the coated substrates differ accordingly.

For the production of relief structures, the substrate coated with the photoresist composition is exposed imagewise. The term ‘imagewise’ exposure includes both exposure through a photomask containing a predetermined pattern, exposure by means of a computer controlled laser beam which is moved over the surface of the coated substrate, exposure by means of computer-controlled electron beams, and exposure by means of X-rays or UV rays through a corresponding mask.

Radiation sources, which can be used, are all sources that emit radiation to which the photoacid generator is sensitive. Examples include high pressure mercury lamp, KrF excimer lasers, ArF excimer lasers, electron beams and x-rays sources.

The process described above for the production of relief structures preferably includes, as a further process measure, heating of the coating between exposure and treatment with the developer. With the aid of this heat treatment, known as “post-exposure bake”, virtually complete reaction of the acid labile groups in the polymer resin with the acid generated by the exposure is achieved. The duration and temperature of this post-exposure bake can vary within broad limits and depend essentially on the functionalities of the polymer resin, the type of acid generator and on the concentration of these two components. The exposed resist is typically subjected to temperatures of about 50° C. to 150° C. for a few seconds to a few minutes. The preferred post exposure bake is from about 80° C. to 130° C. for about 5 seconds to 300 seconds.

After imagewise exposure and any heat treatment of the material, the exposed areas of the photoresist are removed by dissolution in a developer. The choice of the particular developer depends on the type of photoresist; in particular on the nature of the polymer resin or the photolysis products generated. The developer can include aqueous solutions of bases to which organic solvents or mixtures thereof may have been added. Particularly preferred developers are aqueous alkaline solutions. These include, for example, aqueous solutions of alkali metal silicates, phosphates, hydroxides and carbonates, but in particular of tetra alkylammonium hydroxides, and more preferably tetramethylammonium hydroxide (TMAH). If desired, relatively small amounts of wetting agents and/or organic solvents can also be added to these solutions.

After the development step, the substrate carrying the resist coating is generally subjected to at least one further treatment step which changes substrate in areas not covered by the photoresist coating. Typically, this can be implantation of a dopant, deposition of another material on the substrate or an etching of the substrate. This is usually followed by the removal of the resist coating from the substrate typically by an oxygen plasma etch or a wet solvent strip.

The invention further relates to a method of forming a pattern. The method employs the photoresist compositions of the present invention, which include the polymers of the present invention. The method comprises the steps of coating a substrate with a resist that contain the polymers of the present invention, baking to remove excessive solvent from the resulting film, exposure of the resulting coated substrate to actinic radiation, optionally baking the resulting film, i.e., post exposure baking, to improve the quality of the resulting image, followed by development in an alkaline developer solution, rinsing and drying.

The aspects of the present invention are illustrated by, but not limited to, the following examples.

Monomers used in preparing polymers of the present invention and comparative polymers are synthesized in the following preparations.

Preparation 1: Synthesis of 4-Acryloyl-4-Methyl-2-Pentanone

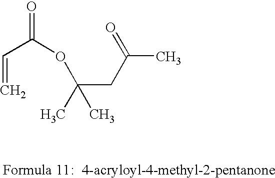

A 1-L three neck round bottom flask and a 250-mL addition funnel were oven dried at 120° C. for three hours prior to use. Acryloyl chloride was removed from cold storage and allowed to warm completely to room temperature prior to use.

The vessel and addition funnel were removed from the oven and assembled. The apparatus was further equipped with overhead stirring, and a thermometer and inert gas inlet adapter combination, and the equipment was cooled to room temperature under a flow of nitrogen. 4-hydroxy-4-methyl-2-pentanone (100 g, 0.861 mol), triethylamine (130.67 g, 1.291 mol), phenothiazine (20.00 g, 0.10 mol) and acetone (300 g) were charged to the reactor and acryloyl chloride (116.88 g, 1.291 mol) was charged to the addition funnel. The reactor was then cooled to <10° C. by application of an ice bath, whereupon acryloyl chloride was added at such a rate to keep the temperature <20° C. Upon completion of the addition the ice bath was removed and the reaction was allowed to proceed overnight.

The reaction mixture was then quenched by addition of 350 mL of water, and transferred to a 1-L separatory funnel. The organic phase was decanted and reserved while the aqueous phase was extracted with 150 mL of a 50:50 mixture of methyl tert-butyl ether (MTBE) and ethyl acetate (EtOAc). The combined organic phase was then extracted twice with 150 mL of NaCl (5% aqueous) and finally partitioned between 150 mL of water and 150 mL of MTBE. The organic phase was then dried over magnesium sulfate and concentrated at reduced pressure. Vacuum distillation of this material at 250 mTorr afforded 30 mL of a clear liquid which was 94% pure by gas chromatography.

Preparation 2: Synthesis of 3-Acryloyl-2-Butanone

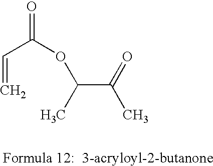

A 1-L three neck round bottom flask and a 250-mL addition funnel were oven dried at 120° C. for three hours prior to use. Acryloyl chloride was removed from cold storage and allowed to warm completely to room temperature prior to use.

The vessel and addition funnel were removed from the oven and assembled. The apparatus was further equipped with overhead stirring and a combination thermometer/inert gas inlet adapter, and the equipment was cooled to room temperature under a flow of nitrogen. 3-Hydroxy-2-butanone (100 g, 1.1349 mol), triethylamine (172.27 g, 1.7024 mol), phenothiazine (20.00 g, 0.10 mol) and acetone (395.51 g) were charged to the reactor and acryloyl chloride (154.09 g, 1.7024 mol) and THF (88.9 g, 1.2328 mol) were charged to the addition funnel. The reactor was then cooled by application of an ice bath while acryloyl chloride was added at such a rate to keep T<30° C. Upon completion of the addition the ice bath was removed and the reaction was allowed to proceed overnight.

After the overnight hold, a further 40 mL of triethylamine (0.286 mol) was added dropwise to the reactor. The reaction mixture was then quenched by addition of 250 mL of water, and pH was made neutral by addition of 40 mL of acetic acid (0.70 mol) and transferred to a 2-L separatory funnel. 250 mL of hexane and 500 mL of ethyl acetate were added to force phase separation. The organic phase was decanted and reserved while the aqueous phase was extracted twice with 250 mL of methyl tert-butyl ether (MTBE) each time. The combined organic phase was then extracted once with 200 mL of water and twice with 250 mL of NaCl (5% aqueous). The organic phase was then dried over magnesium sulfate and concentrated at reduced pressure. Vacuum distillation of this material at 800 mTorr afforded 105 g of a clear liquid which was 96% pure by gas chromatography.

Preparation 3: Synthesis of Ethyl Lactate Acrylate

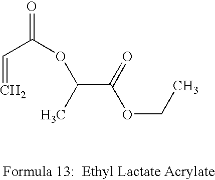

A 2-L three neck round bottom flask and a 500-mL addition funnel were oven dried at 120° C. for three hours prior to use. Acryloyl chloride was removed from cold storage and allowed to warm completely to room temperature prior to use.

The vessel and addition funnel were removed from the oven and assembled. The apparatus was further equipped with overhead stirring and a combination thermometer/inert gas inlet adapter, and the equipment was cooled to room temperature under a flow of nitrogen. Ethyl lactate (150 g, 1.26 mol), phenothiazine (15.00 g, 0.08 mol), and acetone (949 g) were charged to the reactor and stirred to dissolve. Acryloyl chloride (200 g, 2.21 mol) was then added and the reactor was cooled by application of an ice bath. Triethylamine (172.27 g, 1.7024 mol) and acetone (220 g) were charged to the addition funnel. When the reactor was cooled <10° C., the triethylamine solution was added at such a rate to keep T<20° C. Upon completion of the addition the ice bath was removed and the reaction was allowed to proceed overnight.

After the overnight hold, the reaction mixture was quenched by addition of 400 mL of water and transferred to a 4-L separatory funnel. 600 mL of water, 300 mL of methy tert-butyl I ether (MTBE) and 300 mL of ethyl acetate were added to force phase separation. The organic phase was decanted and reserved while the aqueous phase was extracted with a mixture of 300 mL of MTBE and 300 mL of ethyl acetate. The combined organic phase was then extracted 3×600 mL of water and then dried over magnesium sulfate and concentrated at reduced pressure. Vacuum distillation of this material at 75° C. at 250 mTorr afforded 66 g of a clear liquid which was 96% pure by gas chromatography. To remove the remaining 4% of acrylic acid, the product was dissolved in acetone, treated with 30% ammonium hydroxide, and partitioned between MTBE and water. The organic phase was dried, concentrated, and distilled at 55° C./400 mTorr to yield 50 g of 99% pure monomer.

Preparation 4: Synthesis of Naphthalene Methyl Acrylate

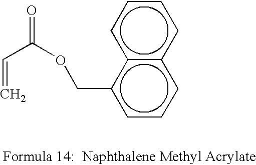

A 2.0-L three neck round bottom flask, a 250-mL addition funnel, and a 9-mm stir shaft and Teflon paddle were oven-dried at 120° C. for three hours. Acryloyl chloride, stored in a refrigerator at 4° C., was removed and allowed to warm to room temperature for 2 hours prior to use.

The glassware was removed under nitrogen, cooled under a jet of nitrogen, and assembled under a nitrogen pad. Naphthalene methanol (100.00 g, 632.1 mmol), triethylamine (95.95 g, 948.2 mmol) and dry acetone (955 g, 1200 mL) were charged to the flask, and stirred to dissolve. Acryloyl chloride (85.82 g, 948.2 mmol) was charged to the addition funnel. Under a pad of dry nitrogen, the contents of the 2.0-L flask were cooled by immersion of the flask in an ice-water bath. When the temperature of the flask has reached 5° C., the acryloyl chloride was added at such a rate to keep temperature less than 15° C. When all the acryloyl chloride was added, the reaction was stirred under nitrogen at 5-10° C. for 30 minutes, and then the ice bath was removed. The reaction I stirred under nitrogen at room temperature for 14 hours. Water (400 g) was then charged to the addition funnel and added to the reaction mixture over approximately 30 minutes. The contents of the flask were then transferred to a 2.0-L separatory funnel. The organic phase was decanted and reserved. The aqueous phase was extracted 2×100 mL of ethyl acetate. The combined organic extracts were then washed 2×400 mL of water, 1×5% potassium carbonate (aqueous), 1×400 mL of 5% sodium chloride (aqueous) and finally 3×200 mL of water. The organic phase was then dried over anhydrous magnesium sulfate and concentrated on a rotary evaporator. Fractional distillation at 250 mTorr of the resulting oil afforded 85 g (˜60% yield) of naphthyl methyl acrylate, 98% purity by HPLC (reverse phase Supelcosil C-18, mobile phase 70% acetonitrile, 30% 0.001 N nitric acid aqueous).

Preparation 5: Synthesis of Tetrahydrofurfuryl Norbornene Carboxylate

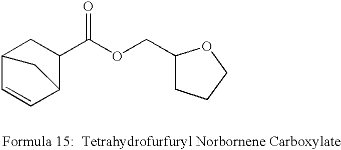

A 250 mL round bottom flask and a 125 mL addition funnel were dried at 120° C. for three hours prior to use. Tetrahydrofurfuryl acrylate was removed from cold storage and allowed to warm completely to room temperature.

The glassware was removed from the oven and cooled under a jet of nitrogen. The flask was equipped with the addition funnel, a reflux condenser with nitrogen inlet adapter and thermometer. Dicyclopentadiene (26.4 g, 200 mmol) was added to the flask and tetrahydrofurfuryl acrylate (56 g, 358 mmol) was charged to the addition funnel. The flask was then heated to 185° C. and held for 15 minutes, whereupon the tetrahydrofurfuryl acrylate was added dropwise over a period of 90 minutes to the flask. After the addition was complete the mixture was kept at 185° C. for 30 min. The product was then separated by means of fractional vacuum distillation. Yield: 65%, purity 98-99% by GC, b.p. 80° C. (0.2 mm. Hg.).

Preparation 6: Synthesis of Ethyl Ethoxy Norbornene Carboxylate

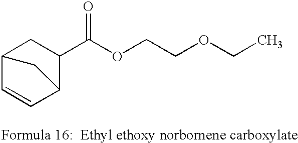

A 250 mL round bottom flask and a 125 mL addition funnel were dried at 120° C. for three hours prior to use. Ethoxyethyl acrylate was removed from cold storage and allowed to warm completely to room temperature.

The glassware was removed from the oven and cooled under a jet of nitrogen. The flask was equipped with the addition funnel, a reflux condenser with nitrogen inlet adapter and thermometer. Dicyclopentadiene (26.4 g, 200 mmol) was added to the flask and ethoxyethyl acrylate (55 g, 381 mmol) was charged to the addition funnel. The flask was then heated to 185° C. and held for 15 minutes, whereupon the ethoxyethyl acrylate was added dropwise over a period of 90 minutes to the flask. After the addition was complete the mixture was kept at 185° C. for 30 min. The product was then separated by means of fractional vacuum distillation. Yield: 40%, purity 98-99% by GC, b.p. 75° C. (0.2 mm. Hg.)

Preparation 7: Synthesis of Ethyl Lactyl Norbornene Caroxylate

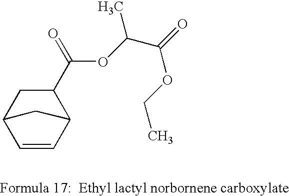

A 2.0-L three-necked round bottom flask, a 250-mL addition funnel with sidearm, an N₂-gas inlet adapter, a thermometer, and a 9-mm glass stir shaft with Teflon paddle were all oven dried at 120° C. for more than 3 hours prior to use.

The glassware was removed from the oven, assembled, and flushed with dry nitrogen for 30 minutes to cool to room temperature. Norbornene carboxylic acid (75 g, 543 mmol) and 500 mL of THF were charged to the flask and the mixture was cooled to 5° C. by means of an ice bath. Trifluroroacetic anhydride [TFAA] (134 g, 637 mmol) was charged to the addition funnel and added dropwise to the reactor at such a rate to keep T<10° C. Upon completion of the addition, the walls of the addition funnel were rinsed with 25 mL of THF, which was allowed to pass into the reactor. The reaction mixture was stirred at temperature for 30 minutes, and then the ice bath was removed. The mixture was allowed to warm to room temperature and react with stirring for 150 minutes. The reaction mixture was then cooled again by application of the ice bath to <5° C. Ethyl lactate (167 g, 1.41 mol) was charged to the addition funnel and added dropwise to the reaction mixture at such a rate to keep T<15° C. . The reaction was stirred at temperature for 15 minutes, and then the ice bath was removed and the mixture was allowed to warm to room temperature and react with stirring overnight.

The reaction mixture was then again cooled to 5° C., and 250 mL of aqueous ammonium hydroxide [NH₄OH] (30% aqueous solution) was added to the reaction mixture dropwise at such a rate to keep T<20° C. The addition takes place over the course of 4 hours. The reaction mixture was then stirred at room temperature for 48 hours. The reaction mixture was then transferred to a 2-L separatory funnel and partitioned between 500 mL of water and 500 mL of hexane. The organic phase was decanted and extracted 1×500 mL of water, 1×500 mL of Na₂CO₃, and finally 1×500 mL of water. The material was then dried over magnesium sulfate and reduced on a rotary evaporator to a thick oil. Fractional distillation of this oil at 90° C. under 400 mTorr vacuum afforded ethyllactyl norbornenecarboxylate, 49% yield, 99% pure by gas chromatographic analysis.

Preparation 8: Synthesis of Norbornene Carboxylate, Pantolactone Ester

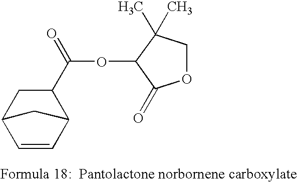

A 2.0-L three-necked round bottom flask, a 250-mL addition funnel with sidearm, an N₂-gas inlet adapter, a thermometer, and a 9-mm glass stir shaft with Teflon paddle were all oven dried at 120° C. for more than 3 hours prior to use.

The glassware was removed from the oven, assembled, and flushed with dry nitrogen for 30 minutes to cool to room temperature. Norbornene carboxylic acid (75 g, 543 mmol) and 500 mL of THF were charged to the flask and the mixture was cooled to 5° C. by means of an ice bath. Trifluroroacetic anhydride [TFAA] (134 g, 637 mmol) was charged to the addition funnel and added dropwise to the reactor at such a rate to keep T<10° C. Upon completion of the addition, the walls of the addition funnel were rinsed with 25 mL of THF, which was allowed to pass into the reactor. The reaction mixture was stirred at temperature for 30 minutes, and then the ice bath was removed. The mixture was allowed to warm to room temperature and react with stirring for 150 minutes. The reaction mixture was then cooled again by application of the ice bath to <5° C. Pantolactone (100 g, 768 mmol) was dissolved in 50 mL of THF and was charged to the addition funnel and added dropwise to the reaction mixture at such a rate to keep T<15° C. The reaction was stirred at temperature for 15 minutes, and then the ice bath was removed and the mixture was allowed to warm to room temperature and react with stirring overnight.

The reaction mixture was then again cooled to 5° C., and 250 mL of aqueous ammonium hydroxide [NH₄OH] (30% aqueous solution) was added to the reaction mixture dropwise at such a rate to keep T<20° C. The addition takes place over the course of 4 hours. The reaction mixture was then stirred at room temperature overnight. The reaction mixture was then transferred to a 2-L separatory funnel and partitioned between 500 mL of water and 500 mL of hexane. The organic phase was decanted and extracted 1×500 mL of water, 1×500 mL of Na₂CO₃, and finally 1×500 mL of water. The material was then dried over magnesium sulfate and reduced on a rotary evaporator to a thick oil. Fractional distillation of this oil at 120° C. under 400 mTorr vacuum afforded pantolactonyl norbornenecarboxylate, 30% yield, 99% pure by gas chromatographic analysis.

Preparation 9: Synthesis of Methyl Cyclohexyl Norbornene Carboxylate

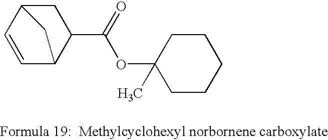

A 2.0-L three-necked round bottom flask, a 250-mL addition funnel with sidearm, an N₂-gas inlet adapter, a thermometer, and a 9-mm glass stir shaft with Teflon paddle were all oven dried at 120° C. for more than 3 is hours prior to use.

The glassware was removed from the oven, assembled, and flushed with dry nitrogen for 30 minutes to cool to room temperature. Norbornene carboxylic acid (75 g, 543 mmol) and 500 mL of THF were charged to the flask and the mixture was cooled to 5° C. by means of an ice bath. Trifluroroacetic anhydride [TFAA] (134 g, 637 mmol) was charged to the addition funnel and added dropwise to the reactor at such a rate to keep T<10° C. Upon completion of the addition, the walls of the addition funnel were rinsed with 25 mL of THF, which was allowed to pass into the reactor. The reaction mixture was stirred at temperature for 30 minutes, and then the ice bath was removed. The mixture was allowed to warm to room temperature and react with stirring for 150 minutes. The reaction mixture was then cooled again by application of the ice bath to <5° C. 1-Methylcyclohexanol (100 g, 876 mmol) was charged to the addition funnel and added dropwise to the reaction mixture at such a rate to keep T<15° C. The reaction was stirred at temperature for 15 minutes, and then the ice bath was removed and the mixture was allowed to warm to room temperature and react with stirring overnight.

The reaction mixture was then again cooled to 5° C., and 250 mL of aqueous ammonium hydroxide [NH₄OH] (30% aqueous solution) was added to the reaction mixture dropwise at such a rate to keep T<20° C. The addition takes place over the course of 4 hours. The reaction mixture was then stirred at room temperature overnight. The reaction mixture was then transferred to a 2-L separatory funnel and partitioned between 500 mL of water and 500 mL of hexane. The organic phase was decanted and extracted 1×500 mL of water, 1×500 mL of Na₂CO₃, and finally 1×500 mL of water. The material was then dried over magnesium sulfate and reduced on a rotary evaporator to a thick oil. Fractional distillation of this oil at 120° C. under 400 mTorr vacuum afforded methylcyclohexyl norbornenecarboxylate, 70% (99% purity by GC).

The following Examples 1 to 16 are Examples of preparation of polymers of this invention and Preparations 10 to 18 are preparations of comparative polymers outside the scope of the invention.

### EXAMPLE 1

### Synthesis of Poly(Norbornene-Maleic Anhydride-t-Butylacrylate-3-Acryloyl-2-butanone) [40/40/16/4]

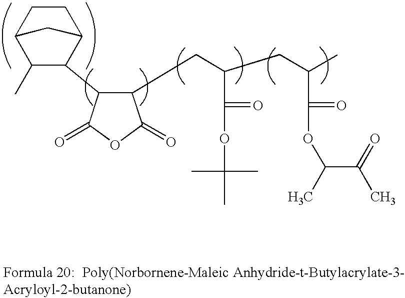

A 250-mL round bottom flask was dried at 120° C. for 3 hours prior to use. tert-Butylacrylate, 3-acryloyl-2-butanone, and Vazo-67 was removed from cold storage and allowed to warm completely to room temperature.

The flask was removed from the oven and cooled under a jet of dry nitrogen. Maleic anhydride (20.83 g, 212.4 mmol) was charged to the flask, and the flask was very quickly equipped with magnetic stirring, reflux condenser with nitrogen inlet adapter, and septum-inlet adapter. Norbornene (20.00 g, 212.4 mmol), tert-butylacrylate (11.57 g, 90.3 mmol), 3-acryloyl-2-butanone (2.26 g, 15.9 mmol) and tetrahydrofuran (52.64 g, 730 mmol) were charged to a beaker and poured into the reactor containing the maleic anhydride under positive flow of nitrogen. The vessel was then heated to 67° C. under a blanket of nitrogen and held for one hour to de-aerate. Vazo-67 (0.6977 g, 4.2 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 28.12 g of an off-white powder.

### EXAMPLE 2

### Synthesis of Poly(Norbornene-Maleic Anhydride-t-Butylacrylate-3-Acryloyl-2-butanone) [40/40/12/8]

A 250-mL round bottom flask was dried at 120° C. for 3 hours prior to use. tert-Butylacrylate, 3-acryloyl-2-butanone, and Vazo-67 was removed from cold storage and allowed to warm completely to room temperature.

The flask was removed from the oven and cooled under a jet of dry nitrogen. Maleic anhydride (26.04 g, 265.5 mmol) was charged to the flask, and the flask was very quickly equipped with magnetic stirring, reflux condenser with nitrogen inlet adapter, and septum-inlet adapter. Norbornene (25.00 g, 265.5 mmol), tert-butylacrylate (10.21 g, 79.7 mmol), 3-acryloyl-2-butanone (7.55 g, 53.1 mmol) and tetrahydrofuran (66.25 g, 919 mmol) were charged to a beaker and poured into the reactor containing the maleic anhydride under positive flow of nitrogen. The vessel was then heated to 67° C. under a blanket of nitrogen and held for one hour to de-aerate. Vazo-67 (1.0209 g, 5.3 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield an off-white powder.

### EXAMPLE 3

### Synthesis of Poly(Norbornene-Maleic Anhydride-t-Butylacrylate-Tetrahydrofurfuryl acrylate) [40/40/16/4]

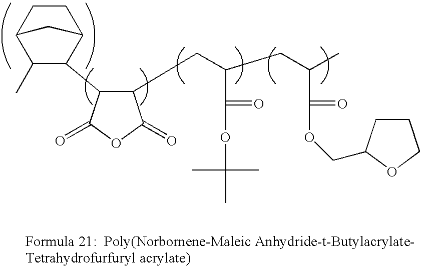

A 250-mL round bottom flask was dried at 120° C. for 3 hours prior to use. tert-Butylacrylate, tetrahydrofurfuryl acrylate, and Vazo-67 were removed from cold storage and allowed to warm completely to room temperature.

The flask was removed from the oven and cooled under a jet of dry nitrogen. Maleic anhydride (26.04 g, 265.5 mmol) was charged to the flask, and the flask was very quickly equipped with magnetic stirring, reflux condenser with nitrogen inlet adapter, and septum-inlet adapter. Norbornene (25.00 g, 265.5 mmol), tert-butylacrylate (13.61 g, 106.2 mmol), tetrahydrofurfuryl acrylate (4.15 g, 26.6 mmol) and tetrahydrofuran (66.25 9, 919 mmol) were charged to a beaker and poured into the reactor containing the maleic anhydride under positive flow of nitrogen. The vessel was then heated to 67° C. under a blanket of nitrogen and held for one hour to de-aerate. Vazo-67 (1.0209 g, 5.3 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 45.17 g of an off-white powder.

### EXAMPLE 4

### Synthesis of Poly(Norbornene-Maleic Anhydride-t-Butylacrylate-Tetrahydrofurfuryl acrylate) [38/38/20/4]

A 250-mL round bottom flask was dried at 120° C. for 3 hours prior to use. tert-Butylacrylate, tetrahydrofurfuryl acrylate, and Vazo-67 were removed from cold storage and allowed to warm completely to room temperature.

The flask was removed from the oven and cooled under a jet of dry nitrogen. Maleic anhydride (26.04 g, 265.5 mmol) was charged to the flask, and the flask was very quickly equipped with magnetic stirring, reflux condenser with nitrogen inlet adapter, and septum-inlet adapter. Norbornene (25.00 g, 265.5 mmol), tert-butylacrylate (18.03 g, 140.7 mmol), tetrahydrofurfuryl acrylate (4.98 g, 31.9 mmol) and tetrahydrofuran (71.31 g, 989 mmol) were charged to a beaker and poured into the reactor containing the maleic anhydride under positive flow of nitrogen. The vessel was then heated to 67° C. under a blanket of nitrogen and held for one hour to de-aerate. Vazo-67 (1.0209 g, 5.3 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 42.45 g of an off-white powder.

### EXAMPLE 5

### Synthesis of Poly(Norbornene-Maleic Anhydride-t-Butylacrylate-Ethyl Lactate acrylate) [40/40/16/4]

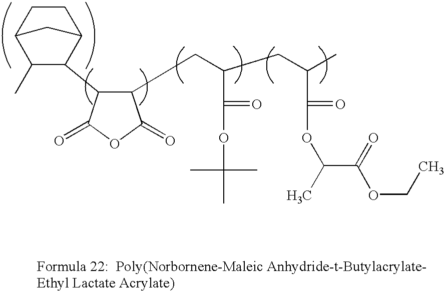

A 250-mL round bottom flask was dried at 120° C. for 3 hours prior to use. tert-Butylacrylate, ethyl lactate acrylate, and Vazo-67 were removed from cold storage and allowed to warm completely to room temperature.

The flask was removed from the oven and cooled under a jet of dry nitrogen. Maleic anhydride (26.04 g, 265.5 mmol) was charged to the flask, and the flask was very quickly equipped with magnetic stirring, reflux condenser with nitrogen inlet adapter, and septum-inlet adapter. Norbornene (25.00 g, 265.5 mmol), tert-butylacrylate (13.61 g, 106.2 mmol), ethyl lactate acrylate (4.57 g, 26.6 mmol) and tetrahydrofuran (66.25 g, 919 mmol) were charged to a beaker and poured into the reactor containing the maleic anhydride under positive flow of nitrogen. The vessel was then heated to 67° C. under a blanket of nitrogen and held for one hour to de-aerate. Vazo-67 (1.0209 g, 5.3 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 39.14 g of an off-white powder.

### EXAMPLE 6

### Synthesis of Poly(Norbornene-Maleic Anhydride-t-Butylacrylate-Ethyl Lactate Acrylate) [38/38/20/4]

A 250-mL round bottom flask was dried at 120° C. for 3 hours prior to use. tert-Butylacrylate, ethyl lactate acrylate, and Vazo-67 were removed from cold storage and allowed to warm completely to room temperature.

The flask was removed from the oven and cooled under a jet of dry nitrogen. Maleic anhydride (26.04 g, 265.5 mmol) was charged to the flask, and the flask was very quickly equipped with magnetic stirring, reflux condenser with nitrogen inlet adapter, and septum-inlet adapter. Norbornene (25.00 g, 265.5 mmol), tert-butylacrylate (18.03 g,140.7 mmol), ethyl lactate acrylate (5.49 g, 31.9 mmol) and tetrahydrofuran (71.31 g, 989 mmol) were charged to a beaker and poured into the reactor containing the maleic anhydride under positive flow of nitrogen. The vessel was then heated to 67° C. under a blanket of nitrogen and held for one hour to de-aerate. Vazo-67 (1.0209 g, 5.3 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 42.76 g of an off-white powder.

### EXAMPLE 7

### Synthesis of Poly(Norbornene-Maleic Anhydride-t-Butylacrylate-Diethylene glycol acrylate) [40/40/16/4]

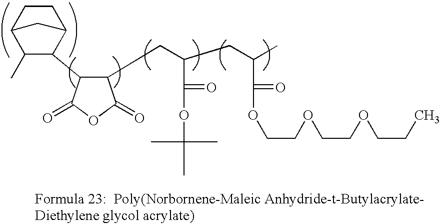

A 250-mL round bottom flask was dried at 120° C. for 3 hours prior to use. tert-Butylacrylate, diethylene glycol acrylate, and Vazo-67 were removed from cold storage and allowed to warm completely to room temperature.

The flask was removed from the oven and cooled under a jet of dry nitrogen. Maleic anhydride (26.04 g, 265.5 mmol) was charged to the flask, and the flask was very quickly equipped with magnetic stirring, reflux condenser with nitrogen inlet adapter, and septum-inlet adapter. Norbornene (25.00 g, 265.5 mmol), tert-butylacrylate (13.61 g, 106.2 mmol), diethylene glycol acrylate (3.83 g, 20.3 mmol) and tetrahydrofuran (65.95 g, 915 mmol) were charged to a beaker and poured into the reactor containing the maleic anhydride under positive flow of nitrogen. The vessel was then heated to 67° C. under a blanket of nitrogen and held for one hour to de-aerate. Vazo-67 (1.0209 g, 5.3 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 42.26 g of an off-white powder.

### EXAMPLE 8

### Synthesis of Poly(Norbornene-Maleic Anhydride-t-Butylacrylate-Diethylene glycol acrylate) [38/38/20/4]

A 250-mL round bottom flask was dried at 120° C. for 3 hours prior to use. tert-Butylacrylate, diethylene glycol acrylate, and Vazo-67 were removed from cold storage and allowed to warm completely to room temperature.

The flask was removed from the oven and cooled under a jet of dry nitrogen. Maleic anhydride (26.04 g, 265.5 mmol) was charged to the flask, and the flask was very quickly equipped with magnetic stirring, reflux condenser with nitrogen inlet adapter, and septum-inlet adapter. Norbornene (25.00 g, 265.5 mmol), tert-butylacrylate (18.03 g, 140.7 mmol), diethylene glycol acrylate (4.59 g, 24.4 mmol) and tetrahydrofuran (71.31 g, 989 mmol) were charged to a beaker and poured into the reactor containing the maleic anhydride under positive flow of nitrogen. The vessel was then heated to 67° C. under a blanket of nitrogen and held for one hour to de-aerate. Vazo-67 (1.0209 g, 5.3 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield an off-white powder.

### EXAMPLE 9

### Synthesis of Poly(Allyltrimethylsilane-Maleic Anhydride-t-Butylacrylate-3-Acryloyl-2-butanone) [33/33/25/9 ]

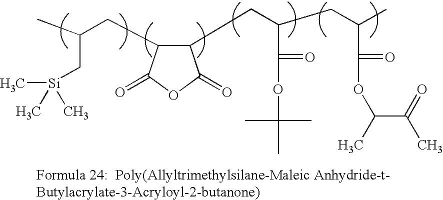

A 250-mL round bottom flask was dried at 120° C. for 3 hours prior to use. tert-Butylacrylate, 3-acryloyl-2-butanone, allyl trimethylsilane, and Vazo-67 were removed from cold storage and allowed to warm completely to room temperature.

The flask was removed from the oven and cooled under a jet of dry nitrogen. Maleic anhydride (29.44 g, 300 mmol) was charged to the flask, and the flask was very quickly equipped with magnetic stirring, reflux condenser with nitrogen inlet adapter, and septum-inlet adapter.

Allyltrimethylsilane (34.3 g, 300 mmol), tert-butylacrylate (29.12 g, 227 mmol), 3-acryloyl-2-butanone (11.56 g, 81.4 mmol) and tetrahydrofuran (88.75 g, 1.231 mol) were charged to a beaker and poured into the reactor containing the maleic anhydride under positive flow of nitrogen. The is vessel was then heated to 67° C. under a blanket of nitrogen and held for one hour to de-aerate. Vazo-67 (0.5772 g, 3.0 mmol) was dissolved in 2 mL of tetrahydrofuran, and after the one-hour hold, the solution was injected into the reaction mixture through the septum inlet adapter. The reaction was then allowed to proceed for 24 hours at 67° C. with stirring under a nitrogen blanket. The reactor was then cooled to room temperature, and the polymerization mixture was precipitated by dropwise addition to 1400 mL of hexane under a blanket of dry nitrogen. The resulting solids were collected by filtration, rinsed with fresh hexane, and dried at 60° C. under high vacuum for 12 hours. The resulting polymer was reprecipitated from THF/Hexane to yield 79.4 g of an off-white powder.

### EXAMPLE 10

### Synthesis of Poly(Allyltrimethylsilane-Maleic Anhydride-t-Butylacrylate-1-Naphthalene Methylacrylate-3-Acryloyl-2-butanone) [32/32/21/5/10]

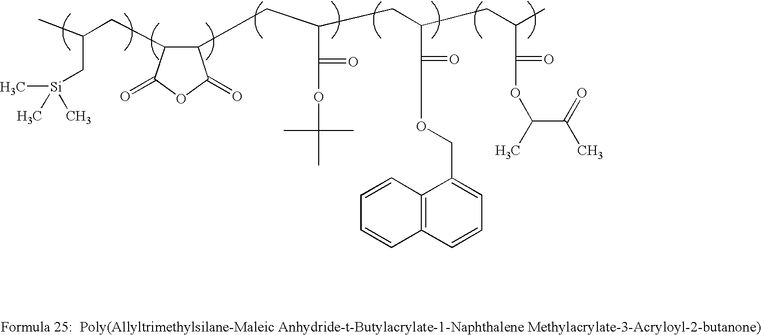

A 250-mL round bottom flask was dried at 120° C. for 3 hours prior to use. tert-Butylacrylate, 3-acryloyl-2-butanone, allyl trimethylsilane, naphthalene methyl acrylate, and Vazo-67 were removed from cold storage and allowed to warm completely to room temperature.

The flask was removed from the oven and cooled under a jet of dry nitrogen. Maleic anhydride (21.46 g, 219 mmol) was charged to the flask, and the flask was very quickly equipped with magnetic stirring, reflux condenser with nitrogen inlet adapter, and septum-inlet adapter. Allyltrimethylsilane (25.0 g, 219 mmol), tert-butylacrylate (18.31 g, 143 mmol), naphthalene methyl acrylate (7.58 g, 35.7 mol), 3-acryloyl-2-butanone (10.15 g, 71.4 mmol) and tetrahydrofuran (73.34 g, 1.02 mol) were charged to a beaker and poured into the reactor containing the maleic anhydride under positive flow of nitrogen. The vessel was then heated to 67° C. under a blanket of nitrogen and held for one hour to de-aerate. Vazo-67 (0.3872 g, 2.4 mmol) was dissolved in 2 mL of tetrahydrofuran, and after the one-hour hold, the solution was injected into the reaction mixture through the septum inlet adapter. The reaction was then allowed to proceed for 24 hours at 67° C. with stirring under a nitrogen blanket. The reactor was then cooled to room temperature, and the polymerization mixture was precipitated by dropwise addition to 1400 mL of hexane under a blanket of dry nitrogen. The resulting solids were collected by filtration, rinsed with fresh hexane, and dried at 60° C. under high vacuum for 12 hours. The resulting polymer was reprecipitated from THF/Hexane to yield an off-white powder.

### EXAMPLE 11

### Synthesis of Poly(Allyltrimethyisilane-Maleic Anhydride-t-Butylacrylate-1-Naphthalene Methylacrylate-3-Acryloyl-2-butanone) [32/32/26/5/5]

A 250-mL round bottom flask was dried at 120° C. for 3 hours prior to use. tert-Butylacrylate, 3-acryloyl-2-butanone, allyl trimethylsilane, naphthalene methyl acrylate, and Vazo-67 were removed from cold storage and allowed to warm completely to room temperature.

The flask was removed from the oven and cooled under a jet of dry nitrogen. Maleic anhydride (21.46 g, 219 mmol) was charged to the flask, and the flask was very quickly equipped with magnetic stirring, reflux condenser with nitrogen inlet adapter, and septum-inlet adapter. Allyltrimethylsilane (25.0 g, 219 mmol), tert-butylacrylate (22.89 g, 179 mmol), naphthalene methyl acrylate (7.58 g, 35.7 mol), 3-acryloyl-2-butanone (5.08 g, 35.7 mmol) and tetrahydrofuran (72.9 g, 1.01 mol) were charged to a beaker and poured into the reactor containing the maleic anhydride under positive flow of nitrogen. The vessel was then heated to 67° C. under a blanket of nitrogen and held for one hour to de-aerate. Vazo-67 (0.3594 g, 2.2 mmol) was dissolved in 2 mL of tetrahydrofuran, and after the one-hour hold, the solution was injected into the reaction mixture through the septum inlet adapter. The reaction was then allowed to proceed for 24 hours at 67° C. with stirring under a nitrogen blanket. The reactor was then cooled to room temperature, and the polymerization mixture was precipitated by dropwise addition to 1400 mL of hexane under a blanket of dry nitrogen. The resulting solids were collected by filtration, rinsed with fresh hexane, and dried at 60° C. under high vacuum for 12 hours. The resulting polymer was reprecipitated from THF/Hexane to yield 20.91 g of an off-white powder.

### EXAMPLE 12

### Synthesis of Poly(Allyltrimethylsilane-Maleic Anhydride-t-Butylacrylate-1-Naphthalene Methylacrylate-Tetrahydrofurfuryl acrylate) [32/32/21/5/10]

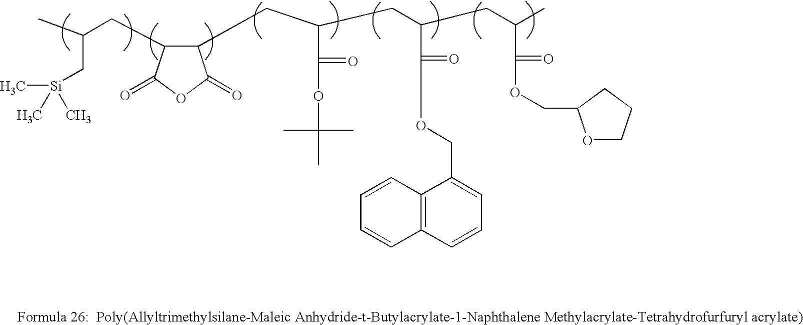

A 250-mL round bottom flask was dried at 120° C. for 3 hours prior to use. tert-Butylacrylate, tetrahydrofurfuryl acrylate, allyl trimethylsilane, naphthalene methyl acrylate, and Vazo-67 were removed from cold storage and allowed to warm completely to room temperature.

The flask was removed from the oven and cooled under a jet of dry nitrogen. Maleic anhydride (21.46 g, 219 mmol) was charged to the flask, and the flask was very quickly equipped with magnetic stirring, reflux condenser with nitrogen inlet adapter, and septum-inlet adapter. Allyltrimethylsilane (25.0 g, 219 mmol), tert-butylacrylate (18.31 g, 143 mmol), naphthalene methyl acrylate (7.58 g, 35.7 mol), tetrahydrofurfuryl acrylate (11.16 g, 71.4 mmol) and tetrahydrofuran (78.3 g, 1.09 mol) were charged to a beaker and poured into the reactor containing the maleic anhydride under positive flow of nitrogen. The vessel was then heated to 67° C. under a blanket of nitrogen and held for one hour to de-aerate. Vazo-67 (0.3594 g, 2.2 mmol) was dissolved in 2 mL of tetrahydrofuran, and after the one-hour hold, the solution was injected into the reaction mixture through the septum inlet adapter. The reaction was then allowed to proceed for 24 hours at 67° C. with stirring under a nitrogen blanket. The reactor was then cooled to room temperature, and the polymerization mixture was precipitated by dropwise addition to 1400 mL of hexane under a blanket of dry nitrogen. The resulting solids were collected by filtration, rinsed with fresh hexane, and dried at 60° C. under high vacuum for 12 hours. The resulting polymer was reprecipitated from THF/Hexane to yield 49.03 g of an off-white powder.

### EXAMPLE 13

### Synthesis of Poly(Allyltrimethylsilane-Maleic Anhydride-t-Butylacrylate-1-Naphthalene Methylacrylate-Tetrahydrofurfuryl acrylate) [32/32/26/5/5]

A 250-mL round bottom flask was dried at 120° C. for 3 hours prior to use. tert-Butylacrylate, tetrahydrofurfuryl acrylate, allyl trimethylsilane, naphthalene methyl acrylate, and Vazo-67 were removed from cold storage and allowed to warm completely to room temperature.

The flask was removed from the oven and cooled under a jet of dry nitrogen. Maleic anhydride (21.46 g, 219 mmol) was charged to the flask, and the flask was very quickly equipped with magnetic stirring, reflux condenser with nitrogen inlet adapter, and septum-inlet adapter. Allyltrimethylsilane (25.0 g, 219 mmol), tert-butylacrylate (22.89 g, 179 mmol), naphthalene methyl acrylate (7.58 g, 35.7 mol), tetrahydrofurfuryl acrylate (5.58 g, 35.7 mmol) and tetrahydrofuran (73.34 g, 1.02 mol) were charged to a beaker and poured into the reactor containing the maleic anhydride under positive flow of nitrogen. The vessel was then heated to 67° C. under a blanket of nitrogen and held for one hour to de-aerate. Vazo-67 (0.3594 g, 2.2 mmol) was dissolved in 2 mL of tetrahydrofuran, and after the one-hour hold, the solution was injected into the reaction mixture through the septum inlet adapter. The reaction was then allowed to proceed for 24 hours at 67° C. with stirring under a nitrogen blanket. The reactor was then cooled to room temperature, and the polymerization mixture was precipitated by dropwise addition to 1400 mL of hexane under a blanket of dry nitrogen. The resulting solids were collected by filtration, rinsed with fresh hexane, and dried at 60° C. under high vacuum for 12 hours. The resulting polymer was reprecipitated from THF/Hexane to yield 42.47 g of an off-white powder.

### EXAMPLE 14

### Synthesis of Poly (Tetrahydrofurfuryl Norbornene Carboxylate-Maleic Anhydride-Methylcyclohexyl Norbornene Carboxylate)

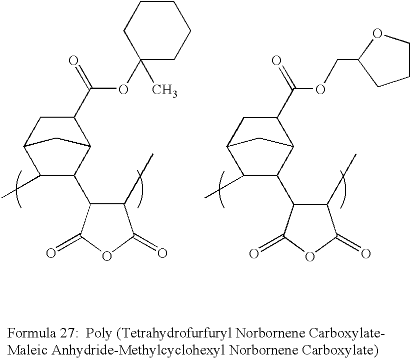

A 250-mL round bottom flask was dried at 120° C. for 3 hours prior to use. Tetrahydrofurfurylnorbornene carboxylate, methylcyclohexylnorbornene carboxylate and lauroyl peroxide were removed from cold storage and allowed to warm completely to room temperature prior to use.

The flask was removed from the oven and cooled under a jet of dry nitrogen. Maleic anhydride (9.31 g, 95 mmol) was charged to the flask, and the flask was very quickly equipped with magnetic stirring, reflux condenser with nitrogen inlet adapter, and septum-inlet adapter. Tetrahydrofurfurylnorbornene carboxylate from Example 25 (4.2 g, 19 mmol), methylcyclohexyl norbornene carboxylate from Example 29 (16 g, 68 mmol) and toluene (7 mL) were charged to a beaker and poured into the reactor containing the maleic anhydride under positive flow of nitrogen. The vessel was then heated to 67° C. under a blanket of nitrogen and held for one hour to de-aerate. Lauroyl peroxide (2.2 g, 5.52 mmol) was then added in one portion. The reaction was then allowed to proceed for 48 hours at 67° C. with stirring under a nitrogen blanket. The reactor was then cooled to room temperature, and the reaction mixture was diluted with 30 mL of tetrahydrofuran. The polymerization mixture was then precipitated by dropwise addition to a mixture of 300 mL of hexane and 300 mL of methyl tert-butyl ether under a blanket of dry nitrogen. The resulting solids were collected by filtration, rinsed with fresh hexane, and air-dried. The resulting polymer was redissolved in 30 mL of THF, reprecipitated from THF/Hexane and dried at 60° C. under high vacuum for 12 hours to yield 15.5 g of an off-white powder.

### EXAMPLE 15

### Synthesis of Poly(Ethoxyethyl Norbornene Carboxylate-Maleic Anhydride-Methylcyclohexyl Norbornene Carboxylate)

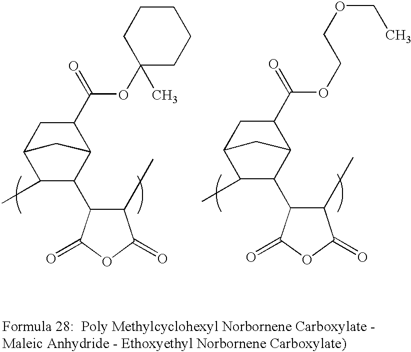

A 250-mL round bottom flask was dried at 120° C. for 3 hours prior to use. Ethoxyethyinorbornene carboxylate, methylcyclohexylnorbornene carboxylate and lauroyl peroxide were removed from cold storage and allowed to warm completely to room temperature prior to use.

The flask was removed from the oven and cooled under a jet of dry nitrogen. Maleic anhydride (8.25 g, 84 mmol) was charged to the flask, and the flask was very quickly equipped with magnetic stirring, reflux condenser with nitrogen inlet adapter, and septum-inlet adapter. Ethoxyethyinorbornene carboxylate from Example 26 (3.53 g, 17 mmol), methylcyclohexyl norbornene carboxylate from Example 29 (15.71 g, 67 mmol) and toluene (7 mL) were charged to a beaker and poured into the reactor containing the maleic anhydride under positive flow of nitrogen. The vessel was then heated to 67° C. under a blanket of nitrogen and held for one hour to de-aerate. Lauroyl peroxide (2.2 g, 5.52 mmol) was then added in one portion. The reaction was then allowed to proceed for 48 hours at 67° C. with stirring under a nitrogen blanket. The reactor was then cooled to room temperature, and the reaction mixture was diluted with 30 mL of tetrahydrofuran. The polymerization mixture was then precipitated by dropwise addition to a mixture of 300 mL of hexane and 300 mL of methyl tert-butyl ether under a blanket of dry nitrogen. The resulting solids were collected by filtration, rinsed with fresh hexane, and air-dried. The resulting polymer was redissolved in 30 mL of THF, reprecipitated from THF/Hexane and dried at 60° C. under high vacuum for 12 hours to yield 15.12 g (54%) of an off-white powder.

### EXAMPLE 16

### Synthesis of Poly(Ethyl Lactate Norbornene Carboxylate-Maleic Anhydride-Methylcyclohexyl Norbornene Carboxylate)

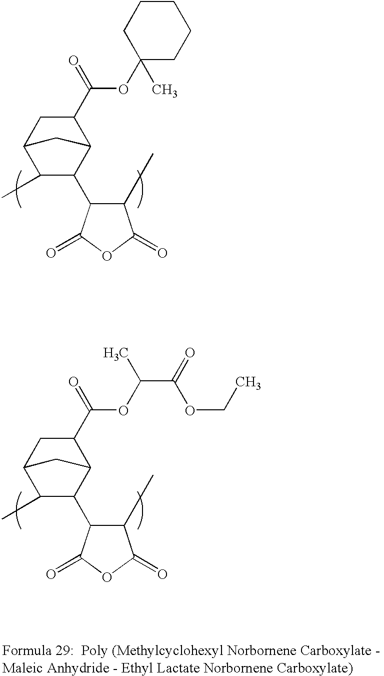

A 250-mL round bottom flask was dried at 120° C. for 3 hours prior to use. Ethyl lactate norbornene carboxylate, methylcyclohexylnorbornene carboxylate and lauroyl peroxide were removed from cold storage and allowed to warm completely to room temperature prior to use.

The flask was removed from the oven and cooled under a jet of dry nitrogen. Maleic anhydride (7.84 g, 80 mmol) was charged to the flask, and the flask was very quickly equipped with magnetic stirring, reflux condenser with nitrogen inlet adapter, and septum-inlet adapter. Ethyl lactate norbornene carboxylate from Example 27 (3.81 g, 16 mmol), methylcyclohexyl norbornene carboxylate from Example 29 (15.00 g, 64 mmol) and toluene (7 mL) were charged to a beaker and poured into the reactor containing the maleic anhydride under positive flow of nitrogen. The vessel was then heated to 67° C. under a blanket of nitrogen and held for one hour to de-aerate. Lauroyl peroxide (2.2 g, 5.52 mmol) was then added in one portion. The reaction was then allowed to proceed for 48 hours at 67° C. with stirring under a nitrogen blanket. The reactor was then cooled to room temperature, and the reaction mixture was diluted with 30 mL of tetrahydrofuran. The polymerization mixture was then precipitated by dropwise addition to a mixture of 300 mL of hexane and 300 mL of methyl tert-butyl ether under a blanket of dry nitrogen. The resulting solids were collected by filtration, rinsed with fresh hexane, and air-dried. The resulting polymer was redissolved in 30 mL of THF, reprecipitated from THF/Hexane and dried at 60° C. under high vacuum for 12 hours to yield 14.3 g (50%) of an off-white powder.

The following Preparations 10-18 are preparations of polymers for purpose of comparing their lithographic performance to that of the polymers of this invention.

Preparation 10: Synthesis of Poly (Norbornene-Maleic Anhydride-t-Butylacrylate-4-Acryloyl-4-methyl -2-pentanone)

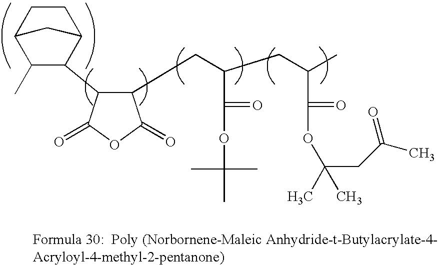

A 250-mL round bottom flask was dried at 120° C. for 3 hours prior to use. tert-Butylacrylate, 4-acryloyl-4-methyl-2-pentanone, and Vazo-67 was removed from cold storage and allowed to warm completely to room temperature.

The flask was removed from the oven and cooled under a jet of dry nitrogen. Maleic anhydride (20.83 g, 212.4 mmol) was charged to the flask, and the flask was very quickly equipped with magnetic stirring, reflux condenser with nitrogen inlet adapter, and septum-inlet adapter. Norbornene (20.00 g, 212.4 mmol), tert-butylacrylate (11.57 g, 90.3 mmol), 4-Acryloyl-4-methyl-2-pentanone (2.71 g, 15.9 mmol) and tetrahydrofuran (53.07 g, 736 mmol) were charged to a beaker and poured into the reactor containing the maleic anhydride under positive flow of nitrogen. The vessel was then heated to 67° C. under a blanket of nitrogen and held for one hour to de-aerate. Vazo-67 (0.6977 g, 4.2 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 26.64 g of an off-white powder.

Preparation 11: Synthesis of Poly(Norbornene-Maleic Anhydride-t-Butylacrylate-β-Methacryloyl-y-butyrolactone):

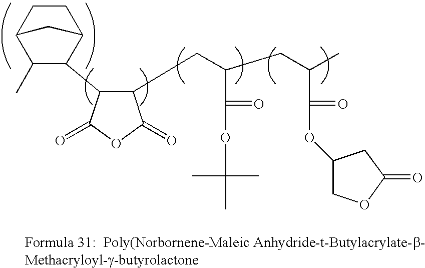

A 250-mL round bottom flask was dried at 120° C. for 3 hours prior to use. tert-Butylacrylate, β-methacryloyl-γ-butyrolactone, and Vazo-67 were removed from cold storage and allowed to warm completely to room temperature.

The flask was removed from the oven and cooled under a jet of dry nitrogen. Maleic anhydride (20.83 g, 212.4 mmol) was charged to the flask, and the flask was very quickly equipped with magnetic stirring, reflux condenser with nitrogen inlet adapter, and septum-inlet adapter. Norbornene (20.00 g, 212.4 mmol), tert-butylacrylate (11.57 g, 90.3 mmol), β-methacryloyl-γ-butyrolactone (2.71 g, 15.9 mmol) and tetrahydrofuran (52.64 g, 730 mmol) were charged to a beaker and poured into the reactor containing the maleic anhydride under positive flow of nitrogen. The vessel was then heated to 67° C. under a blanket of nitrogen and held for one hour to de-aerate. Vazo-67 (0.6977 g, 4.2 mmol) was dissolved in 2 mL of tetrahydrofuran, and after the one-hour hold, the solution was injected into the reaction mixture through the septum inlet adapter. The reaction was then allowed to proceed for 36 hours at 67° C. with stirring under a nitrogen blanket. The reactor was then cooled to room temperature, and the polymerization mixture was precipitated by dropwise addition to 1400 mL of methyl-tert-butyl ether under a blanket of dry nitrogen. The resulting solids were collected by filtration, rinsed with fresh methyl-tert-butyl ether, and dried at 60° C. under high vacuum for 12 hours. The resulting polymer was reprecipitated from THF/MTBE to yield 33.95 g of an off-white powder.

Preparation 12: Synthesis of Poly(Allyltrimethylsilane-Maleic Anhydride-t-butylacrylate-4-acryloyl-4-methyl-2-pentanone) [33/33/25/9]

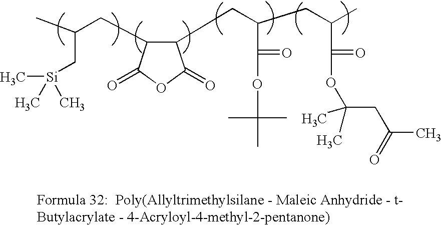

A 250-mL round bottom flask was dried at 120° C. for 3 hours prior to use. tert-Butylacrylate, 4-acryloyl-4-methyl-2-pentanone, allyl trimethylsilane, and Vazo-67 were removed from cold storage and allowed to warm completely to room temperature.

The flask was removed from the oven and cooled under a jet of dry nitrogen. Maleic anhydride (29.44 g, 300 mmol) was charged to the flask, and the flask was very quickly equipped with magnetic stirring, reflux condenser with nitrogen inlet adapter, and septum-inlet adapter. Allyltrimethylsilane (34.3 g, 300 mmol), tert-butylacrylate (29.12 g, 227 mmol), 4-acryloyl-4-methyl-2-pentanone (13.85 g, 81.4 mmol) and tetrahydrofuran (88.75 g, 1.231 mol) were charged to a beaker and poured into the reactor containing the maleic anhydride under positive flow of nitrogen. The vessel was then heated to 67° C. under a blanket of nitrogen and held for one hour to de-aerate. Vazo-67 (0.5772 g, 3.0 mmol) was dissolved in 2 mL of tetrahydrofuran, and after the one-hour hold, the solution was injected into the reaction mixture through the septum inlet adapter. The reaction was then allowed to proceed for 24 hours at 67° C. with stirring under a nitrogen blanket. The reactor was then cooled to room temperature, and the polymerization mixture was precipitated by dropwise addition to 1400 mL of hexane under a blanket of dry nitrogen. The resulting solids were collected by filtration, rinsed with fresh hexane, and dried at 60° C. under high vacuum for 12 hours. The resulting polymer was reprecipitated from THF/Hexane to yield 73.3 g of an off-white powder.

Preparation 13: Synthesis of Poly(Allyltrimethylsilane-Maleic Anhydride-t-Butylacrylate-β-Methacryloy-γ-butyrolactone) [33/33/25/9]

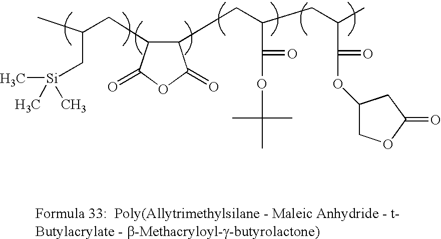

A 250-mL round bottom flask was dried at 120° C. for 3 hours prior to use. tert-Butylacrylate, β-methacryloyl-γ-butyrolactone, allyl trimethylsilane, and Vazo-67 were removed from cold storage and allowed to warm completely to room temperature.

The flask was removed from the oven and cooled under a jet of dry nitrogen. Maleic anhydride (29.44 g, 300 mmol) was charged to the flask, and the flask was very quickly equipped with magnetic stirring, reflux condenser with nitrogen inlet adapter, and septum-inlet adapter. Allyltrimethylsilane (34.3 g, 300 mmol), tert-butylacrylate (29.12 g, 227 mmol), β-methacryloyl-γ-butyrolactone (11.56 g, 81.4 mmol) and tetrahydrofuran (88.75 g, 1.231 mol) were charged to a beaker and poured into the reactor containing the maleic anhydride under positive flow of nitrogen. The vessel was then heated to 67° C. under a blanket of nitrogen and held for one hour to de-aerate. Vazo-67 (0.5772 g, 3.0 mmol) was dissolved in 2 mL of tetrahydrofuran, and after the one-hour hold, the solution was injected into the reaction mixture through the septum inlet adapter. The reaction was then allowed to proceed for 24 hours at 67° C. with stirring under a nitrogen blanket. The reactor was then cooled to room temperature, and the polymerization mixture was precipitated by dropwise addition to 1400 mL of hexane under a blanket of dry nitrogen. The resulting solids were collected by filtration, rinsed with fresh hexane, and dried at 60° C. under high vacuum for 12 hours. The resulting polymer was reprecipitated from THF/Hexane to yield 78.4 g of an off-white powder.

Preparation 14 Synthesis of Poly(Allyltrimethylsilane-Maleic Anhydride-t-Butylacrylate-Methylacrylate) [33/33/25/9]

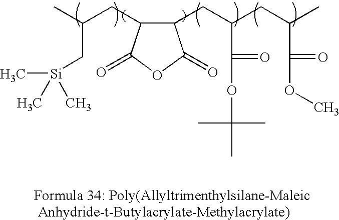

A 250-mL round bottom flask was oven dried at 120° C. for 3 hours prior to use. tert-Butylacrylate, allyl trimethylsilane, methyl acrylate, and Vazo-67 were removed from cold storage and allowed to warm completely to room temperature.

The flask was removed from the oven, cooled under a jet of nitrogen, and equipped with magnetic stirring, reflux condenser fitted with N2-inlet adapter, and septum inlet adapter. Allyl-trimethylsilane (25.00 g, 218.8 mmol), maleic anhydride (21.46 g, 218.8 mmol), t-butylacrylate ( 21.24 g, 165.8 mmol), methyl acrylate (5.28 g, 59.3 mmol), and anhydrous, inhibitor-free tetrahydrofuran (64.01 g, 887 mmol) were charged to the flask under a positive flow of nitrogen. The flask was then heated to 67° C., and azobis(2-methylbutanenitrile) (0.3594 g, 2.2 mmol) dissolved in 2 mL of tetrahydrofuran were injected to the reactor via the septum inlet adapter. The reaction was allowed to proceed under a nitrogen blanket for 22 hours, and was then cooled to room temperature. The reaction mixture was diluted by addition of 50 mL of dry tetrahydrofuran, and precipitated by dropwise addition to 1400 mL of dry hexanes under a nitrogen pad. The resulting solids were collected by filtration, rinsed, and dried under vacuum. The dry solids were then redissolved in 50 mL of tetrahydrofuran and re-precipitated into 1400 mL of hexanes. The resulting solids were collected by filtration, rinsed, and dried to constant weight under high vacuum at 70° C. to yield 41 g of a white powder (85% conversion).

### Preparation 15: Synthesis of Poly(Allyltrimethylsilane-Maleic Anhydride-t-Butylacrylate-Naphthalene-Methylacrylate) [33/33/25/9]

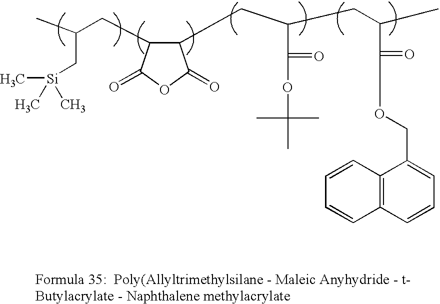

A 250-mL round bottom flask was oven dried at 120° C. for 3 hours prior to use. tert-Butylacrylate, allyl trimethylsilane, naphthalene methyl acrylate, and Vazo-67 were removed from cold storage and allowed to warm completely to room temperature.

The flask was removed from the oven, cooled under a jet of nitrogen, and equipped with magnetic stirring, reflux condenser fitted with N2-inlet adapter, and septum inlet adapter. Allyl-trimethylsilane (25.00 g, 218.8 mmol), maleic anhydride (21.46 g, 218.8 mmol), t-butylacrylate ( 21.24 g, 165.8 mmol), naphthyl methyl acrylate (14.07 g, 66.3 mmol), and anhydrous, inhibitor-free tetrahydrofuran (64.01 g, 887 mmol) were charged to the flask under a positive flow of nitrogen. The flask was then heated to 67° C., and Vazo-67 (0.3594 g, 2.2 mmol) dissolved in 2 mL of tetrahydrofuran was injected to the reactor via the septum inlet adapter. The reaction was allowed to proceed under a nitrogen blanket for 22 hours, and was then cooled to room temperature. The reaction mixture was diluted by addition of 50 mL of dry tetrahydrofuran, and precipitated by dropwise addition to 1400 mL of dry hexanes under a nitrogen pad. The resulting solids were collected by filtration, rinsed, and dried under vacuum. The dry solids were then redissolved in 50 mL of tetrahydrofuran and re-precipitated into 1400 mL of hexanes. The resulting solids were collected by filtration, rinsed, and dried to constant weight under high vacuum at 70° C. to yield 30.7 g of a white powder (38% conversion).

Preparation 16: Synthesis of Poly (Norbornene-Maleic Anhydride-t-Butyl-Acrylate) Comparative Example

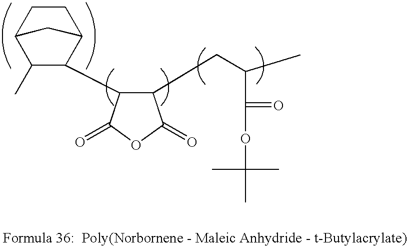

A 500-mL round bottom flask was oven dried at 120° C. for 3 hours prior to use. tert-Butylacrylate and Vazo-67 were removed from cold storage and allowed to warm completely to room temperature.

The flask was removed from the oven, cooled under a jet of nitrogen, and equipped with magnetic stirring, reflux condenser fitted with N2-inlet adapter, and septum inlet adapter. Norbornene (75.00 g, 797 mmol), maleic anhydride (78.11 g, 797 mmol), t-butylacrylate (51.04 g, 398 mmol), and anhydrous, inhibitor-free tetrahydrofuran (197 g, 2.73 mol) were charged to the flask under a positive flow of nitrogen. The flask was then heated to 67° C., and Vazo-67 (1.5314 g, 8 mmol) dissolved in 4 mL of tetrahydrofuran was injected to the reactor via the septum inlet adapter. The reaction was allowed to proceed under a nitrogen blanket for 36 hours, and was then cooled to room temperature. The reaction mixture was diluted by addition of 50 mL of dry tetrahydrofuran, and precipitated by dropwise addition to 3000 mL of dry methyl tert-butyl ether under a nitrogen pad. The resulting solids were collected by filtration, rinsed, and dried under vacuum. The dry solids were then redissolved in 200 mL of tetrahydrofuran and re-precipitated into 3000 mL of MTBE. The resulting solids were collected by filtration, rinsed, and dried to constant weight under high vacuum at 70° C. to yield 106 g of a white powder (52% conversion).

Preparation 17: Synthesis of Poly(Pantolactone Norbornene Carboxylate-Maleic Anhydride-Methylcyclohexyl Norbornene Carboxylate)

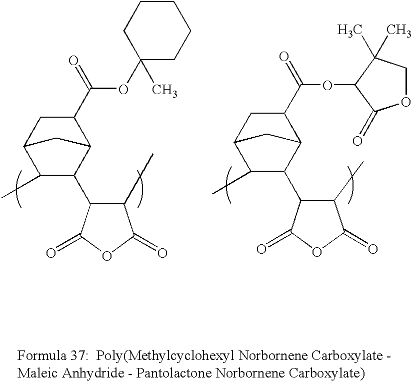

A 250-mL round bottom flask was dried at 120° C. for 3 hours prior to use. Pantolactone norbornene carboxylate, methylcyclohexylnorbornene carboxylate and lauroyl peroxide were removed from cold storage and allowed to warm completely to room temperature prior to use.

The flask was removed from the oven and cooled under a jet of dry nitrogen. Maleic anhydride (9.31 g, 95 mmol) was charged to the flask, and the flask was very quickly equipped with magnetic stirring, reflux condenser with nitrogen inlet adapter, and septum-inlet adapter. Pantolactone norbornene carboxylate from Example 28 (5.02 g, 20 mmol), methylcyclohexyl norbornene carboxylate from Example 29 (16.00 g, 68 mmol) and toluene (7 mL) were charged to a beaker and poured into the reactor containing the maleic anhydride under positive flow of nitrogen. The vessel was then heated to 67° C. under a blanket of nitrogen and held for one hour to de-aerate. Lauroyl peroxide (2.2 g, 5.52 mmol) was then added in one portion. The reaction was then allowed to proceed for 48 hours at 67° C. with stirring under a nitrogen blanket. The reactor was then cooled to room temperature, and the reaction mixture was diluted with 30 mL of tetrahydrofuran. The polymerization mixture was then precipitated by dropwise addition to a mixture of 300 mL of hexane and 300 mL of methyl tert-butyl ether under a blanket of dry nitrogen. The resulting solids were collected by filtration, rinsed with fresh hexane, and air-dried. The resulting polymer was redissolved in 30 mL of tetrahydrofuran (THF), reprecipitated from THF/Hexane and dried at 60° C. under high vacuum for 12 hours to yield 20.0 g (61%) of an off-white powder.

Preparation 18: Synthesis of Poly(Methylcyclohexyl Norbornene-co-Carboxylate Maleic Anhydride)

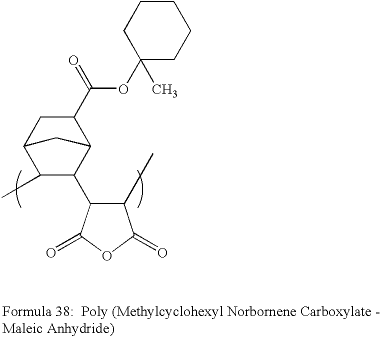

A 250-mL round bottom flask was dried at 120° C. for 3 hours prior to use. Methylcyclohexylnorbornene carboxylate and lauroyl peroxide were removed from cold storage and allowed to warm completely to room temperature prior to use.

The flask was removed from the oven and cooled under a jet of dry nitrogen. Maleic anhydride (7.35 g, 75 mmol) was charged to the flask, and the flask was very quickly equipped with magnetic stirring, reflux condenser with nitrogen inlet adapter, and septum-inlet adapter. Methylcyclohexyl norbornene carboxylate from Example 29 (17.55 g, 75 mmol) and toluene (7 mL) were charged to a beaker and poured into the reactor containing the maleic anhydride under positive flow of nitrogen. The vessel was then heated to 67° C. under a blanket of nitrogen and held for one hour to de-aerate. Lauroyl peroxide (2.2 g, 5.52 mmol) was then added in one portion. The reaction was then allowed to proceed for 48 hours at 67° C. with stirring under a nitrogen blanket. The reactor was then cooled to room temperature, and the reaction mixture was diluted with 30 mL of tetrahydrofuran. The polymerization mixture was then precipitated by dropwise addition to a mixture of 300 mL of hexane and 300 mL of methyl tert-butyl ether under a blanket of dry nitrogen. The resulting solids were collected by filtration, rinsed with fresh hexane, and air-dried. The resulting polymer was redissolved in 30 mL of THF, reprecipitated from MTBE/Hexane and dried at 60° C. under high vacuum for 12 hours to yield 12.6 g (46%) of an off-white powder.

The following lithographic tests and their results illustrate the novel advantageous properties of the polymers of this invention compared to comparative polymers.

In the first test, solutions were made by mixing 13.2 parts by weight of polymer from the Examples with 0.27 parts by weight of a photoacid generator of the structure shown as PAG-1, 0.009 parts by weight of a base of the structure shown as B-1, 0.009 parts by weight of a base shown by the structure B-2, 5.15 parts by weight of 2-heptanone, and 81.4 parts by weight of propylene glycol monomethyl ether acetate, and then filtered through 0.2 μm Teflon filters.

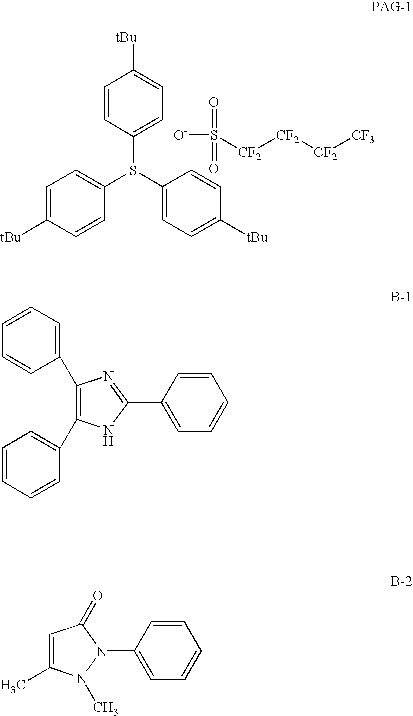

The solutions were then spin coated onto silicon wafers, which were coated with an organic bottom anti-reflecting coating (Brewer Sciences EXP99060) at a thickness of 875 Å and baked at 205° for 60 seconds. The photoresist films were coated to 4100 Å thickness and baked at 145° C. to remove residual solvent. The wafers were then exposed imagewise on an ISI Microstep (ArF, 193 nm) with numerical aperture of 0.6 and partial coherence 0.7. The wafers were post-expose baked at 170° C. for 90 seconds, and developed in a commercially available 0.262 N tetramethylammonium hydroxide developer solution (OPD-262, available from Arch Chemical Company). The resulting fine patterns were then visualized on a scanning electron microscope. Table 1 shows the lithographic results of this first test.

TABLE 1

| # | Polymer | Sensitivity | Resolution | Image Quality |
|---|---|---|---|---|
| L1-1 | Prep. 16 | 9.5 mJ/cm² | 130 nm | Tapered profiles |
| L1-2 | Prep. 10 7 | 11.0 mJ/cm² | 140 nm | Heavy footing, rough |
| | | | | sidewall |
| L1-3 | Example 1 | 10.5 mJ/cm² | 130 nm | No footing, flat tops |
| L1-4 | Prep. 10 | 10.5 mJ/cm² | — | Adhesion failure |

In this test, the utility of the β-oxo esters is clearly demonstrated over the prior art. Comparison of L1-1 to L1-2 through L1-4 show the effects of the added monomers versus a control with no property-enhancing group added. Comparing examples L1-2 and L1-3, it is shown that the position of the ketone β to the ester oxygen provides a large, unexpected, positive effect: footing is much reduced and the resoltion is substantially better. Comparing examples L1-3 and L1-4, it is shown that the effects of the ketone are more positive than the effects of the lactone; the lactone-containing polymer was unable to adhere to the substrate.

In the second test, 8.45 parts by weight of polymers from the Examples, 0.423 parts by weight of Photoacid generator PAG-2, 0.0122 parts by weight of base B-3 and 91.55 parts by weight of propyleneglycol monomethyl ether acetate were mixed to dissolve, and then filtered through 0.2 μm Teflon filters.

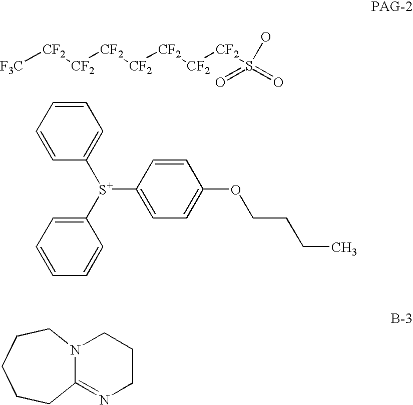

The solutions were then spin coated onto silicon wafers which were coated with an underlayer, one of the thermally cured undercoats described in WO 00/54105, which is coated to a thickness of 5000 Å and baked at 205° C. for 70 seconds. The photoresists are coated, and baked at 125° C. for 60 seconds to achieve a final film thickness of 2350 Å. The wafers were then exposed imagewise on an ISI Microstep (ArF, 193 nm) with numerical aperture of 0.6 and partial coherence 0.7. The wafers were post-expose baked at 135° C. for 60 seconds, and developed in a commercially available 0.262 N tetramethylammonium hydroxide developer solution (OPD-4262, available from Arch Chemical Company). The resulting fine patterns were then visualized on a scanning electron microscope. Table 2 shows the lithographic results of this second test.

TABLE 2

| # | Polymer | Sensitivity | Resolution | Image Quality |
|---|---|---|---|---|
| L2-1 | Prep. 14 | 7.5 mJ/cm² | 100 nm | Square tops, tapered |
| | | | | profiles |
| L2-2 | Prep. 12 | 7.0 mJ/cm² | 100 nm | Large foot, top round |
| L2-3 | Example 9 | 7.5 mJ/cm² | 90 nm | Square profile, flat tops |
| L2-4 | Prep. 13 | 9.5 mJ/cm² | 115 nm | Heavy foot and top round |

The utility of the β-oxo esters is again clearly demonstrated over the prior art, in a different polymer matrix. Comparison of L2-1 and L2-3 shows the beneficial effects of the added monomers of the present invention versus a control with no property-enhancing group added. Comparing examples L2-2 and L2-3, it is shown that the position of the ketone β to the ester oxygen provides a large, unexpected, positive effect: the tops of the lines are flat and the resolution is substantially better. Comparing examples L2-3 and L2-4, and Examples L2-1 and L2-4, it is shown that the effects of the ketone are more positive than the effects of the lactone; in this particular instance, the effect of the lactone was simply to degrade performance compared to polymer with no property-enhancing group.

In the third test, 14.23 parts by weight of polymers from the Examples, 0.75 parts by weight of PAG-3, 0.012 parts by weight of base B-4, 0.006 parts by weight of base B-2, 0.002 parts by weight of base B-5, and 85 parts by weight of propyleneglycol monomethyl ether acetate were mixed to dissolve, and the resulting solutions were filtered through 0.2 μm Teflon filters.

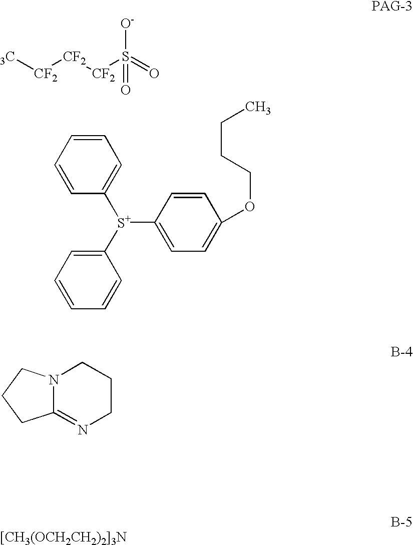

The solutions were then spin coated onto silicon wafers which were coated with an underlayer, TIS-2200UL available from Arch Chemicals, which is coated to a thickness of 5000 Å and baked at 205° C. for 70 seconds. The photoresists are coated, and baked at 125° C. for 60 seconds to achieve a final film thickness of 2350 Å. The wafers were then exposed imagewise on a Canon EX6 (KrF, 248 nm). The wafers were post-expose baked at 135° C. for 60 seconds, and developed in a commercially available 0.262 N tetramethylammonium hydroxide developer solution (OPD-4262, available from Arch Chemical Company). The resulting fine patterns were then visualized on a scanning electron microscope. Table 3 shows the lithographic results of this third test.

TABLE 3

| # | Polymer | Sensitivity | Resolution | DOF | Image Quality |
|---|---|---|---|---|---|
| L3-1 | Prep. 15 | 22 mJ/cm² | 110 nm | 0.3 | Foot, tapering, round top |
| L3-2 | Example 10 | 23 mJ/cm² | 110 nm | 0.5 | Flat top, no taper |
| L3-3 | Example 11 | 26 mJ/cm² | 110 nm | 0.4 | Flat Top, no taper |
| L3-4 | Example 13 | 23 mJ/cm² | 100 nm | 0.4 | Flat top, square profile |

Examples L3-2, L3-3, and L3-4 show the effects of the added monomers versus a control (Example L3-1) which has no property-enhancing group. Comparing examples L3-2 and L3-3, it is shown that the amount of the β-oxo compound (ketone in this instance) provides a large, unexpected, positive effect on the sensitivity and depth of focus. Comparing examples L3-3 and L3-4, it is shown that the identity of the β-oxo group is less important than its position: unexpectedly, ether groups gave the same improvements in DOF and profile quality as the ketones.

In the fourth test, 11.74 parts by weight of polymers from the Examples, 0.24 parts by weight of PAG-1, 0.016 parts by weight of base B-1, and 88 parts by weight of propyleneglycol monomethyl ether acetate were mixed to dissolve, and the resulting solutions were filtered through 0.2 μm Teflon filters.

The solutions were then spin coated onto silicon wafers, which were coated with an organic bottom anti-reflecting coating (Brewer Sciences EXP99060) at a thickness of 875 Å and baked at 205° for 60 seconds. The photoresist films were coated to 4100 Å thickness and baked at 145° C. to remove residual solvent. The wafers were then exposed imagewise on an ISI Microstep (ArF, 193 nm) with numerical aperture of 0.6 and partial coherence 0.7 (“conventional illumination”), or under ¾ annular illumination. The wafers were post-expose baked at 170° C. for 90 seconds, and developed in a commercially available 0.262 N tetramethylammonium hydroxide developer solution (OPD-262, available from Arch Chemical Company). The resulting fine patterns were then visualized on a scanning electron microscope. Table 4 shows the lithographic results of this fourth test.

TABLE 4

| # | Polymer | Sensitivity | Illumination | Resolution | Comments |
|---|---|---|---|---|---|
| L4-1 | Prep. 18 | 21 mJ/cm² | Conventional | None | Image collapsing |
| L4-2 | Example 16 | 24 mJ/cm² | Conventional | 0.125 mm | Slightly sloped profiles |
| L4-3 | Example 15 | 23 mJ/cm² | Conventional | 0.125 mm | Slightly sloped profiles |
| L4-4 | Prep. 17 | 20 mJ/cm² | Annular | 0.11 mm | Eroded tops |
| L4-5 | Example 15 | 24 mJ/cm² | Annular | 0.105 | Square profile |
| L4-6 | Example 14 | 25 mJ/cm² | Annular | 0.11 | Square profile |

Comparison of examples L4-2 and L4-3 with L4-1 shows that incorporation of β-oxo monomers into the polymer provides a benefit in terms of prevention of pattern collapse under conventional illumination.

Under annular illumination, example L4-4, which is a material anticipated in the prior art, performs worse than either of two embodiments of the is current invention, L4-5 and L4-6, in terms of profile and the fact that L4-4 is shown to lose film as evidenced by the eroded tops.

The polymers materials synthesized under the Examples and Preparations and evaluated under the Test Results section provide specific points of difference between the polymers of the current invention (Examples 1 to 16) and the polymers (Preparations 10 to 18) described in the prior art. In all cases, the polymers of the prior art have been shown to yield inferior results. Furthermore, other advantages of the current invention are evident upon consideration of the general art.

β-Oxo polymers of the present invention have been shown to outperform polymers based on lactone monomers as shown in Tests 1, 2, and 4. In all of these tests, the use of the β-oxo material improved performance relative to both the control material which had no property-modifying group at all (Preparations 10, 12, 14, 16 and 18), as well as to a lactone-containing material (Preparations 11, 13 and 33). In Test 1 in particular the lactone monomer was even shown to degrade the performance relative to the material with no property-modifying group. Therefore, the invention is not obvious and provides unexpected advantages which are not predicted in the lactone or lactam art disclosed in U.S. Pat. Nos. 5,968,713 and 6,013,416; EP 1020767A1 and references contained therein; EP0930541A1, Example 12; EP 0999474A1; J. Photopolym. Sci. and Technol., 10, No. 4,(1997) p. 545; J. Photopolym. Sci. and Technol., 9, No. 3,(1996) p. 509; J. Photopolym. Sci. and Technol., 9, No. 3,(1996) p. 475; U.S. Pat. No. 5,750,680; or U.S. Pat. No. 6,051,362.

In Test 1, example L1-2, and Test 2, example L2-2, polymers were tested which are examples of prior art found in U.S. Pat. Nos. 5,929,271; 6,077,644; and 6,087,063. These materials are superficially similar to the materials of the present invention, with two substantial differences. In the prior art, there is no advantage claimed for the position of the polar group. In particular, the examples disclosed in those patents, especially U.S. Pat. No. 6,087,063, have ketonic or other groups which are three to four carbon atoms away from the ester oxygen. However, the test results show (see the results for L1-3 and L2-3), that positioning the ketonic group two carbons away from the ester oxygen, i.e., beta to the oxygen, provides large beneficial effects which are not realized by the materials according to U.S. Pat. Nos. 5,929,271; 6,077,644 and 6,087,063. Furthermore, in the prior art according to U.S. Pat. Nos. 5,929,271; 6,077,644; and 6,087,063, it is a requisite that the polar group be part of the blocking group, and the patents specifically teach that a range of from 20 to 80% by weight of the resin is desirable. In the current invention, the efficiency of the polar group is unexpectedly enhanced by its position on the beta carbon. This in turn provides two benefits: first, lower loadings of the material may be employed, and second, the polar group can be introduced into the polymer independent of the blocking group.

In the examples and data set forth above, the polymers of the current invention have been shown to (1) provide superior lithographic performance to polymers of the prior art; (2) provide unexpected lithographic performance benefits due to the position of the polar group, which was not foreseen by any prior art; and (3) provide a means of introducing the polar group on a specific part of the polymer, a mechanism not available to other systems described in the prior art.

While the invention has been described herein with reference to the specific embodiments thereof, it will be appreciated that changes, modification and variations can be made without departing from the spirit and scope of the inventive concept disclosed herein. Accordingly, it is intended to embrace all such changes, modification and variations that fall with the spirit and scope of the appended claims.

We claim:

1. A polymer prepared by polymerizing a mixture of monomers, comprising:
at least one monomer having an acid labile group; and
at least one β-oxo ester containing monomer which is free of a lactone group.

2. A polymer according to claim 1, wherein said β-oxo ester containing monomer comprises from about 2 to about 20% by weight of the polymer.

3. A polymer according to claim 1, wherein said β-oxo ester containing monomer has an ethylenically unsaturated ester portion and a β-oxo group containing portion covalently bonded to the oxygen of the ester group of said ethylenically unsaturated ester portion through a covalent bond between the oxygen of the ethylenically unsaturated ester portion and the CHR₁— group of the β-oxo group containing portion, said covalent bond being represented as follows:
—O—CHR₁—
wherein R₁ is selected from the group consisting of: alkyl, haloalkyl and an alkylene residue.

4. A polymer according to claim 3, wherein said ethylenically unsaturated ester portion is represented by formula 3 or formula 4: 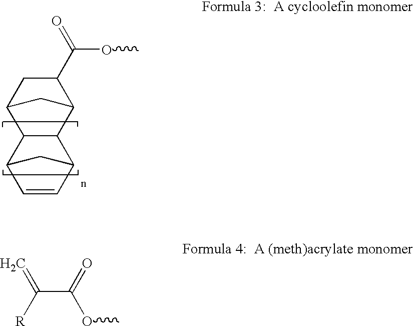
wherein R is selected from the group consisting of: hydrogen, C₁₋₄ alkyl group, CH₂CN, CH₂OR⁴, CH₂C(═O)OR⁴, CH₂OC(═O)R⁴, wherein R⁴ is selected from the group consisting of: substituted or unsubstituted C₁-C₁₀ linear, branched, or cyclic alkyl; substituted or unsubstituted C₁-C₁₀ linear, branched, cyclic or alicyclic alkylene group; and n is an integer of from 0 to 2; and
wherein said covalently bonded β-oxo group containing portion is represented by the formulas 5, 6a, 6b, 7, 8, 9 or 10: 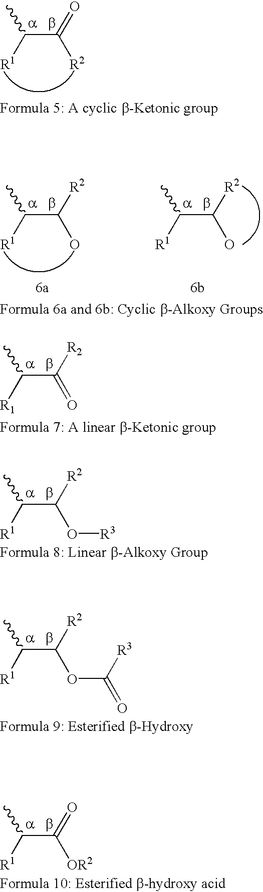
wherein in formula 5, R₁ and R₂ together represent an alkylene group of 2 to 5 carbon atoms to form a 4-, 5-, 6- or 7-membered ring having a β-oxo group; wherein in formula 6a, R₂ is selected from the group consisting of: hydrogen and a C₁₋₄ alkyl group and R₁ represents an alkylene group of 1 to 4 carbon atoms to form a 4-, 5-, 6- or 7-membered ring having a β-oxo group;
wherein in formula 6b, R₁ is selected from the group consisting of: hydrogen and a C₁₋₄ alkyl group and R₂ represents an alkylene group of 2 to 5 carbon atoms to form a 4-, 5-, 6- or 7-membered ring having a β-oxo group;
wherein in formula 7, each of R₁ and R₂ is independently selected from the group consisting of: hydrogen, substituted or unsubstituted linear, branched, cyclic C₁₋₁₀ alkyl group; C₁-C₁₀ fluoroalkyl and substituted or unsubstituted linear, branched, cyclic or alicyclic C₇₋₁₅ alkylene group;
wherein in formula 8, each of R₁, R₂ and R₃ is independently selected from the group consisting of: hydrogen, substituted or unsubstituted linear, branched, cyclic C₁-C₁₀ alkyl group; C₁-C₁₀ fluoroalkyl and substituted or unsubstituted linear, branched, cyclic or alicyclic C₇₋₁₅ alkylene group;
wherein in formula 9, each of R₁, R₂ and R₃ is independently selected from the group consisting of: hydrogen, substituted or unsubstituted linear, branched, cyclic C₁₋₁₀ alkyl group; C₁-C₁₀ fluoroalkyl and substituted or unsubstituted linear, branched, cyclic or alicyclic C₇₋₁₅ alkylene group; and
wherein in formula 10, each of R₁ and R₂ is independently selected from the group consisting of: hydrogen, substituted or unsubstituted linear, branched, cyclic C₁₋₁₀ alkyl group; C₁-C₁₀ fluoroalkyl and substituted or unsubstituted linear, branched, cyclic or alicyclic C₇₋₁₅ alkylene group.

5. A polymer according to claim 4, wherein said R group in said ethylenically unsaturated ester portion in formula 4 is selected from the group consisting of: hydrogen, methyl, ethyl, n-butyl, i-butyl, n-propyl, i-propyl, CH₂CN, CH₂OMe, CH₂O-adamantyl, CH₂OCH₂-adamantyl, CH₂O-cyclohexyl, CH₂O-norbornyl, CH₂OCF₃, CH₂C(═O)OMe, CH₂C(═O)O-cyclopentyl, CH₂C(═O)O-i-propyl, CH₂C(═O)CF₃, CH₂C(═O)OCH₂-cyclohexyl, CH₂OC(═O)CH₂Br, CH₂OC(═O)CH₂Cl, CH₂OC(═O)CF₃, CH₂OC(═O)Me, CH₂OC(═O)-norbornyl, CH₂OC(═O)-adamantyl, CH₂OC(═O)-cyclohexyl and CH₂OC(═O)-tert-butyl.

6. A polymer according to claim 4, wherein said covalently bonded β-oxo group containing portion in formula 6a is selected from the group consisting of:

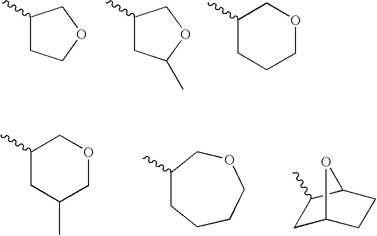

7. A polymer according to claim 4, wherein said covalently bonded β-oxo group containing portion in formula 6b is selected from the group consisting of:

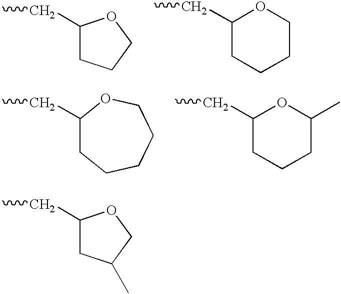

8. A polymer according to claim 4, wherein each of said R¹ and R² groups in said formula 7 is selected from the group consisting of: hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl and norbornyl.

9. A polymer according to claim 8, wherein said covalently bonded β-oxo group containing portion in formula 7 is selected from the group consisting of:

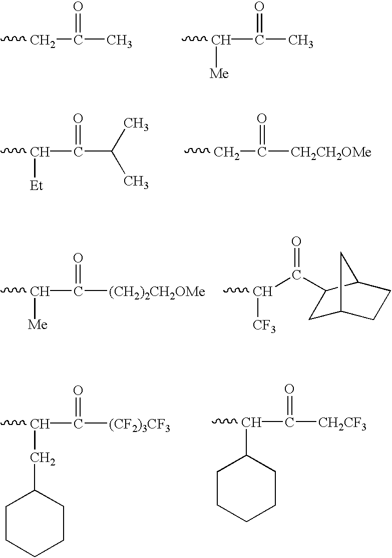

10. A polymer according to claim 4, wherein each of said R¹ and R² groups in said formula 8 is selected from the group consisting of: hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl and norbornyl; and R³ is selected from the group consisting of: methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl, adamantyl and norbornyl.

11. A polymer according to claim 10, wherein said covalently bonded β-oxo group containing portion in formula 8 is selected from the group consisting of:

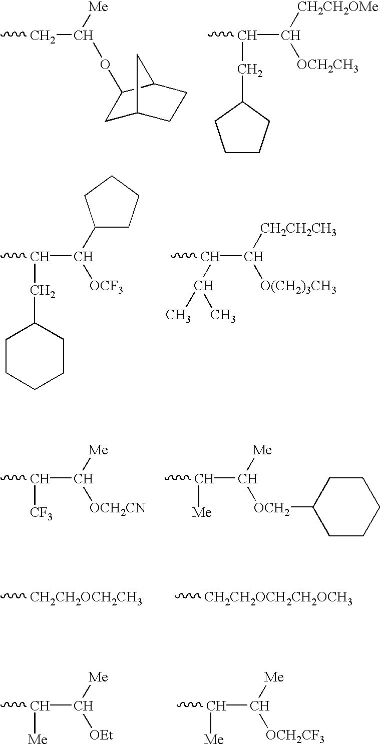

12. A polymer according to claim 4, wherein each of said R¹ and R² groups in said formula 9 is selected from the group consisting of: hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl and norbornyl; and R³ is selected from the group consisting of: methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl, adamantyl and norbornyl.

13. A polymer according to claim 12, wherein said covalently bonded β-oxo group containing portion in formula 8 is selected from the group consisting of:

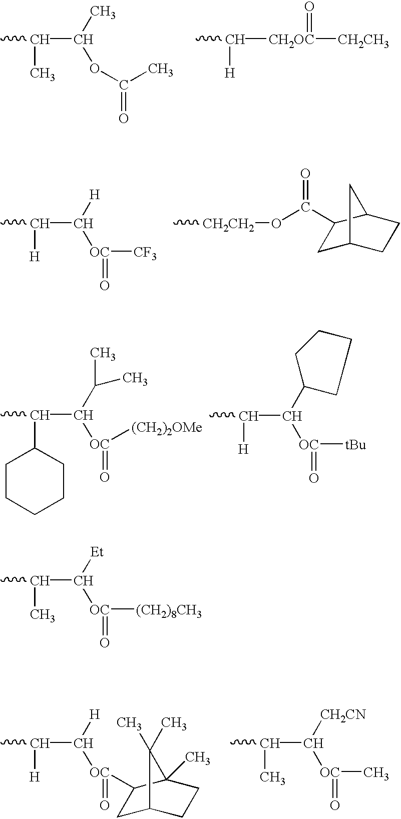

14. A polymer according to claim 4, wherein each of said R¹ and R² groups in said formula 10 is selected from the group consisting of: hydrogen, methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl and norbornyl; and R³ is selected from the group consisting of: methyl, ethyl, t-butyl, butyl, propyl, i-propyl, amyl, t-amyl, sec-amyl, octyl, cyclohexyl, cyclohexylmethyl, cyclopentyl, cyclopentylmethyl, cyclohexylethyl, 4-methoxybutyl, trifluoromethyl, 1,1,1-trifluoroethyl, nonafluorobutyl, adamantyl and norbornyl.

15. A polymer according to claim 14, wherein said covalently bonded β-oxo group containing portion in formula 10 is selected from the group consisting of:

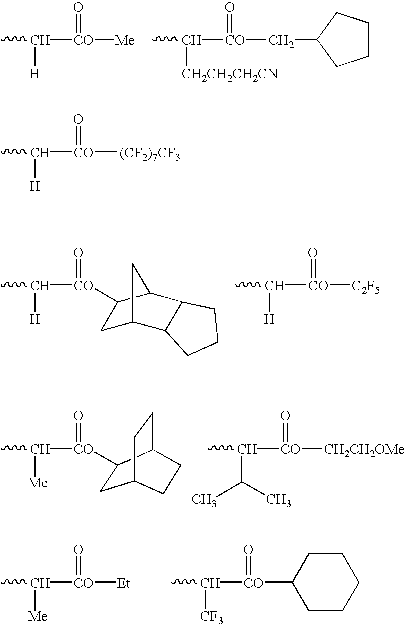

16. A polymer according to claim 4, wherein said β-oxo ester containing monomer is selected from the group consisting of:

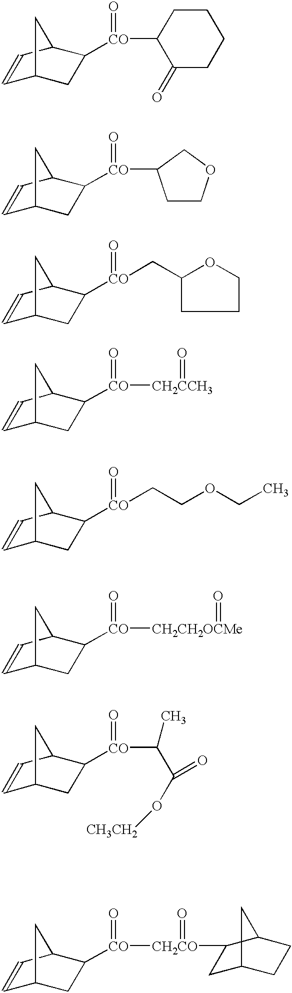

17. A polymer according to claim 4, wherein said β-oxo ester-containing monomer is selected from the group consisting of: 3-acryloyl-2-butanone, ethyl lactate acrylate, tetrahydrofurfuryl norbornene carboxylate, tetrahydrofurfuryl acrylate, ethyl ethoxy norbornene carboxylate and ethyl lactyl norbornene carboxylate.

18. A polymer according to claim 1, wherein said mixture of monomers, further comprises:
at least one comomomer selected from the group consisting of: styrene, naphthalene acrylate, naphthalene methacrylate, vinyl acetate, vinyl chloride, allyltrimethyl silane, vinyltrimethyl silane, norbornene, cyclohexene, maleic anhydride, dialkyl fumarate, maleimide, N-alkylmaleimide, N-arylmaleimide, sulfur dioxide, carbon monoxide, acrylamide, acrylate ester, methacrylate ester and mixtures thereof.

19. A polymer according to claim 18, wherein said mixture of monomers comprises at least one monomer selected from the group consisting of: maleic anhydride, norbornene, t-butyl acrylate, allyltrimethylsilane, naphthalene methacrylate, and methylcyclohexyl norbornene carboxylate.

20. A polymer according to claim 1, selected from the group consisting of: poly(norbornene-maleic anhydride-t-butylacrylate-3-acrolyl-2-butanone), poly(norbornene-maleic anhydride-t-butylacrylate-tetrahydrofurfuryl acrylate), poly(norbornene-maleic anhydride-t-butylacrylate-ethyl lactate acrylate), poly(norbornene-maleic anhydride-t-butylacrylate-diethylene glycol acrylate), poly(allyltrimethylsilane-maleic anhydride-t-butylacrylate-3-acryloyl-2-butanone), poly(allyltrimethylsilane-maleic anhydride-t-butylacrylate-1-naphthalene methylacrylate-3-acryloyl-2-butanone), poly(allyltrimethylsilane-maleic an hydride-t-butylacrylate-1-naphthalene methylacrylate-tetrahyurofurfuryl acrylate), poly(tetrahydrofurfuryl norbornene carboxylate-maleic anhydride-methylcyclohexyl norbornene carboxylate), poly(ethoxyethyl norbornene carboxylate-maleic anhydride-methylcyclohexyl norbornene carboxylate, poly(ethyl lactate norbornene carboxylate-maleic anhydride-methylcyclohexyl norbornene carboxylate) and mixtures thereof.

21. A radiation sensitive photoresist composition comprising:
(a) a polymer prepared by polymerizing a mixture of monomers, comprising: at least one monomer having an acid labile group; and at least one β-oxo ester containing monomer which is free of a lactone group;
(b) a photoacid generator compound; and
(c) a solvent capable of dissolving components (a) and (b).

22. A radiation sensitive photoresist composition according to claim 21, wherein said polymer is selected from the group consisting of: poly(norbornene-maleic anhydride-t-butylacrylate-3-acrolyl-2-butanone), poly(norbornene-maleic anhydride-t-butylacrylate-tetrahydrofurfuryl acrylate), poly(norbornene-maleic anhydride-t-butylacrylate-ethyl lactate acrylate), poly(norbornene-maleic anhydride-t-butylacrylate-diethylene glycol acrylate), poly(allyltrimethylsilane-maleic anhydride-t-butylacrylate-3-acryloyl-2-butanone), poly(allyltrimethylsilane-maleic anhydride-t-butylacrylate-1-naphthalene methylacrylate-3-acryloyl-2-butanone), poly(allyltrimethylsilane-maleic anhydride-t-butylacrylate-1-naphthalene methylacrylate-tetrahydrofurfuryl acrylate), poly(tetrahydrofurfuryl norbornene carboxylate-maleic anhydride-methylcyclohexyl norbornene carboxylate), poly(ethoxyethyl norbornene carboxylate-maleic anhydride-methylcyclohexyl norbornene carboxylate, poly(ethyl lactate norbornene carboxylate-maleic anhydride-methylcyclohexyl norbornene carboxylate) and mixtures thereof.

23. A method of producing a resist image on a substrate, comprising:
coating said substrate with a radiation sensitive photoresist composition comprising:(a) a polymer prepared by polymerizing a mixture of monomers, comprising: at least one monomer having an acid labile group; and at least one β-oxo ester containing monomer which is free of a lactone group; (b) a photoacid generator compound; and (d) a solvent capable of dissolving components (a) and (b);
imagewise exposing said radiation sensitive photoresist composition to actinic radiation to produce an exposed photoresist composition;
developing said exposed photoresist composition with a developer to produce a resist image.

24. A method of producing a resist image on a substrate according to claim 23, wherein said polymer in said radiation sensitive photoresist composition is selected from the group consisting of: poly(norbornene-maleic anhydride-t-butylacrylate-3-acrolyl-2-butanone), poly(norbornene-maleic anhydride-t-butylacrylate-tetrahydrofurfuryl acrylate), poly(norbornene-maleic anhydride-t-butylacrylate-ethyl lactate acrylate), poly(norbornene-maleic anhydride-t-butylacrylate-diethylene glycol acrylate), poly(allyltrimethylsilane-maleic anhydride-t-butylacrylate-3-acryloyl-2-butanone), poly(allyltrimethylsilane-maleic anhydride-t-butylacrylate-1-naphthalene methylacrylate-3-acryloyl-2-butanone), poly(allyltrimethylsilane-maleic anhydride-t-butylacrylate-1-naphthalene methylacrylate-tetrahydrofurfuryl acrylate), poly(tetrahydrofurfuryl norbornene carboxylate-maleic anhydride-methylcyclohexyl norbornene carboxylate), poly(ethoxyethyl norbornene carboxylate-maleic anhydride-methylcyclohexyl norbornene carboxylate, poly(ethyl lactate norbornene carboxylate-maleic anhydride-methylcyclohexyl norbornene carboxylate) and mixtures thereof.

25. A resist image on a substrate, prepared by the method of claim 23.
